(19) United States
(12) Patent Application Publication
(10) Pub. No.: US 2026/0247610 A1
(43) Pub. Date: Aug. 20, 2026

(54) SEMICONDUCTOR DEVICE WITH NECK LAYER AND METHOD FOR FABRICATING THE SAME

(71) Applicant: NANYA TECHNOLOGY CORPORATION, NEW TAIPEI CITY (TW)

(72) Inventor: PING HSU, NEW TAIPEI CITY (TW)

(21) Appl. No.: 19/079,729

(22) Filed: Mar. 14, 2025

Related U.S. Application Data
(63) Continuation of application No. 19/055,762, filed on Feb. 18, 2025.

(51) Int. Cl. H10B 12/00

(52) U.S. Cl. CPC H10B 12/485; H10B 12/0335; H10B 12/315; H10B 12/34; H10B 12/482

(57) ABSTRACT

The present application discloses a semiconductor device and a method for fabricating the semiconductor device. The semiconductor device includes a substrate with an active region; a gate structure disposed in a gate trench in the active region; an impurity region disposed adjacent to the gate structure; at least two bit line structures positioned on the substrate; a contact layer positioned on the substrate and between the at least two bit line structures; and a conductive neck layer positioned on the contact layer and between the at least two bit line structures. The impurity region has an upper portion defining a top surface of the impurity region and a lower portion defining a bottom surface of the impurity region. A width of the top surface of the impurity region is greater than a width of the bottom surface of the impurity region.

### CROSS-REFERENCE TO RELATED APPLICATION

This application is a continuation application of U.S. Non-Provisional application Ser. No. 19/055,762 filed Feb. 18, 2025, which is incorporated herein by reference in its entirety.

### TECHNICAL FIELD

The present disclosure relates to a semiconductor device and a method for fabricating the semiconductor device, and more particularly, to a semiconductor device with a neck layer and a method for fabricating the semiconductor device with the neck layer.

### DISCUSSION OF THE BACKGROUND

Semiconductor devices are used in various electronic applications, including personal computers, cellular telephones, digital cameras, and other electronic equipment. Sizes of semiconductor devices are continuously decreasing to meet growing demands for computing power. However, such scaling down presents challenges that are becoming more frequent and impactful. Therefore, there are still challenges to improving quality, yield, performance and reliability while reducing complexity.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device comprising a substrate with an active region; a gate structure disposed in a gate trench in the active region; an impurity region disposed adjacent to the gate structure; at least two bit line structures positioned on the substrate; a contact layer positioned on the substrate and between the at least two bit line structures; and a conductive neck layer positioned on the contact layer and between the at least two bit line structures. The impurity region has an upper portion defining a top surface of the impurity region and a lower portion defining a bottom surface of the impurity region. A width of the top surface of the impurity region is greater than a width of the bottom surface of the impurity region.

Another aspect of the present disclosure provides a semiconductor device comprising a substrate having a first top surface; a first gate electrode and a second gate electrode disposed in the substrate, wherein the second gate electrode is positioned above the first gate electrode; a first barrier layer and a second barrier layer disposed in the substrate, wherein the second barrier layer is positioned over the first barrier layer and the first gate electrode; a gate capping layer disposed over the second gate electrode; at least two bit line structures positioned on the substrate; a contact layer positioned on the substrate and between the at least two bit line structures; and a conductive neck layer positioned on the contact layer and between the at least two bit line structures. The first gate electrode includes a first member surrounded by the first barrier layer and a second member extending from the first member toward the first top surface and protruding from the first barrier layer. The second gate electrode is positioned on the second barrier layer at a position such that the second gate electrode surrounds the second barrier layer and the second member of the first gate electrode. A width of a top surface of the conductive neck layer is greater than a width of a bottom surface of the conductive neck layer.

Another aspect of the present disclosure provides a method for fabricating a semiconductor device. The method includes providing a substrate having an isolation region, wherein the isolation region defines an active region; forming a gate structure in the substrate; forming at least two bit line structures on the substrate; forming at least two partition layers on the substrate; forming a contact layer on the substrate; and forming a conductive neck layer on the contact layer. A width of a top surface of the conductive neck layer is greater than a width of a bottom surface of the conductive neck layer.

Another aspect of the present disclosure provides a method for fabricating a semiconductor device. The method includes providing a substrate with a first top surface, wherein the substrate includes an isolation region surrounding an active region; forming a gate structure in the active region of the substrate; forming a first recess and a second recess in the substrate and adjacent to the gate structure; forming an impurity region in the first recess and in the second recess; forming at least two bit line structures on the substrate; forming at least two partition layers on the substrate; forming a contact opening over the substrate; forming a contact layer on the substrate and within the contact opening; and forming a conductive neck layer on the contact layer. The contact opening is enclosed by at least two partition layers and the at least two bit line structures. The impurity region has an upper portion defining a top surface of the impurity region and a lower portion defining a bottom surface of the impurity region. A width of the top surface of the impurity region is greater than a width of the bottom surface of the impurity region.

Due to a design of the semiconductor device disclosed herein, overlapping areas between the conductive neck layer and the landing pad can be increased by using a wider top surface for the conductive neck layer. As a result, defects and complexity associated with fabricating the semiconductor device are reduced.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed herein may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in flowchart diagram form, a method for fabricating a semiconductor device in accordance with one embodiment of the present disclosure.

FIG. 2 illustrates, in a schematic top-view diagram, an intermediate semiconductor device in accordance with one embodiment of the present disclosure.

FIG. 3 shows schematic cross-sectional diagrams taken along lines A-A′, B-B′, and C-C′ in FIG. 2.

FIG. 4 illustrates, in a schematic top-view diagram, an intermediate semiconductor device in accordance with one embodiment of the present disclosure.

FIG. 5 shows schematic cross-sectional view diagrams taken along lines A-A′, B-B′, and C-C′ in FIG. 4.

FIG. 6 illustrates, in a schematic top-view diagram, an intermediate semiconductor device in accordance with one embodiment of the present disclosure.

FIG. 7 shows schematic cross-sectional view diagrams taken along lines A-A′, B-B′ and C-C′ in FIG. 6.

FIG. 8 illustrates, in a schematic top-view diagram, an intermediate semiconductor device in accordance with one embodiment of the present disclosure.

FIG. 9 shows schematic cross-sectional view diagrams taken along lines A-A′, B-B′, and C-C′ in FIG. 8 illustrating part of a process for fabricating a semiconductor device in accordance with one embodiment of the present disclosure.

FIG. 10 shows schematic cross-sectional view diagrams taken along lines A-A′, B-B′, and C-C′ in FIG. 8 illustrating part of a process for fabricating a semiconductor device in accordance with one embodiment of the present disclosure.

FIG. 11 illustrates, in a schematic top-view diagram, an intermediate semiconductor device in accordance with one embodiment of the present disclosure.

FIG. 12 shows schematic cross-sectional view diagrams taken along lines A-A′, B-B′, and C-C′ in FIG. 11.

FIG. 13 illustrates, in a schematic top-view diagram, an intermediate semiconductor device in accordance with one embodiment of the present disclosure.

FIG. 14 shows schematic cross-sectional view diagrams taken along lines A-A′, B-B′, and C-C′ in FIG. 13 illustrating part of a process for fabricating a semiconductor device in accordance with one embodiment of the present disclosure.

FIG. 15 shows schematic cross-sectional view diagrams taken along lines A-A′, B-B′, and C-C′ in FIG. 13 illustrating part of a process for fabricating a semiconductor device in accordance with one embodiment of the present disclosure.

FIG. 16 illustrates, in a schematic top-view diagram, an intermediate semiconductor device in accordance with one embodiment of the present disclosure.

FIG. 17 shows schematic cross-sectional view diagrams taken along lines A-A′, B-B′, and C-C′ in FIG. 16.

FIG. 18 illustrates, in a schematic top-view diagram, an intermediate semiconductor device in accordance with one embodiment of the present disclosure.

FIG. 19 shows schematic cross-sectional view diagrams taken along lines A-A′, B-B′, and C-C′ in FIG. 18 illustrating part of a process for fabricating a semiconductor device in accordance with one embodiment of the present disclosure.

FIG. 20 shows schematic cross-sectional view diagrams taken along lines A-A′, B-B′, and C-C′ in FIG. 18 illustrating part of a process for fabricating a semiconductor device in accordance with one embodiment of the present disclosure.

FIG. 21 shows schematic cross-sectional view diagrams taken along lines A-A′, B-B′, and C-C′ in FIG. 18 illustrating part of a process for fabricating a semiconductor device in accordance with one embodiment of the present disclosure.

FIG. 22 illustrates, in a schematic top-view diagram, an intermediate semiconductor device in accordance with one embodiment of the present disclosure.

FIG. 23 shows schematic cross-sectional view diagrams taken along lines A-A′, B-B′, and C-C′ in FIG. 22 illustrating part of a process for fabricating a semiconductor device in accordance with one embodiment of the present disclosure.

FIG. 24 shows schematic cross-sectional view diagrams taken along lines A-A′, B-B′, and C-C′ in FIG. 22 illustrating part of a process for fabricating a semiconductor device in accordance with one embodiment of the present disclosure.

FIG. 25 illustrates, in a schematic top-view diagram, an intermediate semiconductor device in accordance with one embodiment of the present disclosure.

FIG. 26 shows schematic cross-sectional view diagrams taken along lines A-A′, B-B′, and C-C′ in FIG. 25.

FIG. 27 illustrates, in a schematic top-view diagram, an intermediate semiconductor device in accordance with one embodiment of the present disclosure.

FIG. 28 shows schematic cross-sectional views diagram taken along lines A-A′, B-B′, and C-C′ in FIG. 27.

FIGS. 29 to 30 illustrate, in schematic cross-sectional view diagrams, semiconductor devices in accordance with some embodiments of the present disclosure.

FIG. 31 shows schematic cross-sectional views diagram taken along lines A-A′, B-B′, and C-C′ in FIG. 27.

FIGS. 32 to 42 are schematic cross-sectional diagrams taken along the line B-B′ in FIG. 27 illustrating part of a process for fabricating a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures, do not necessarily mean an exactly identical orientation, layout, location, shape, size, amount, or other measure, but are intended to encompass nearly identical orientations, layouts, locations, shapes, sizes, amounts, or other measures within acceptable variations that may occur, for example, due to manufacturing processes. The term “substantially” may be used herein to reflect such meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

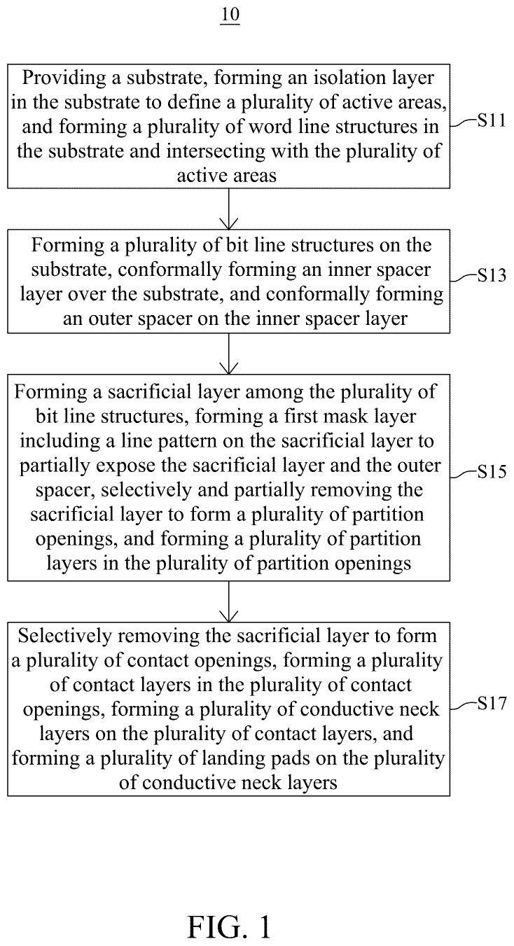

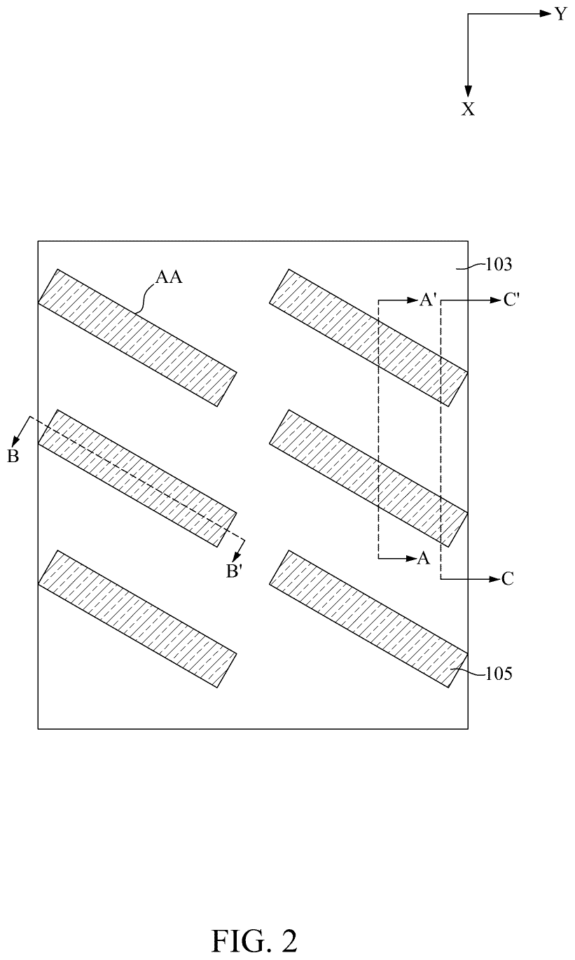

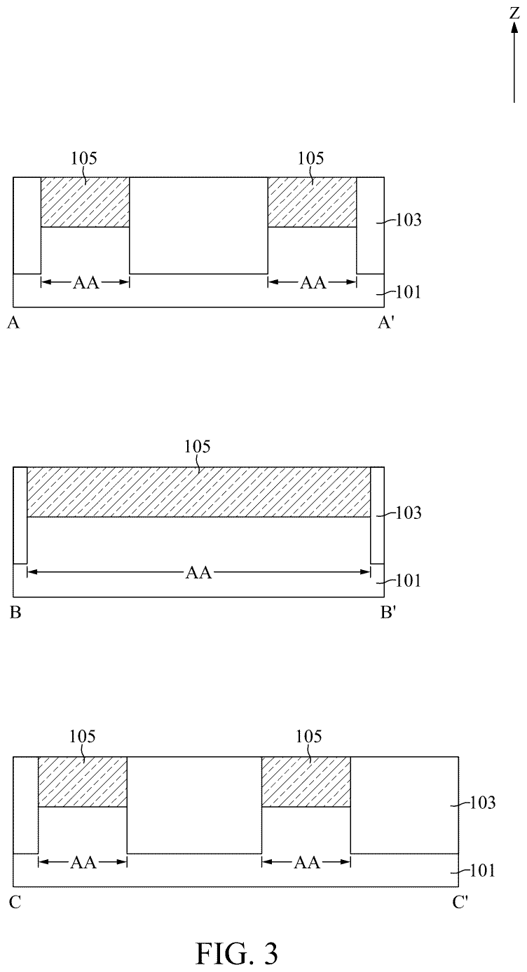

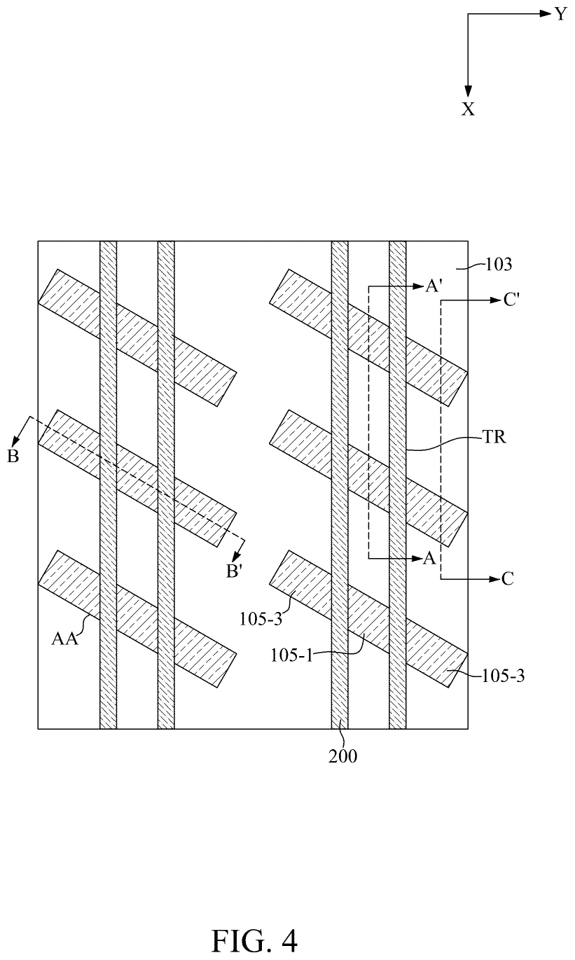

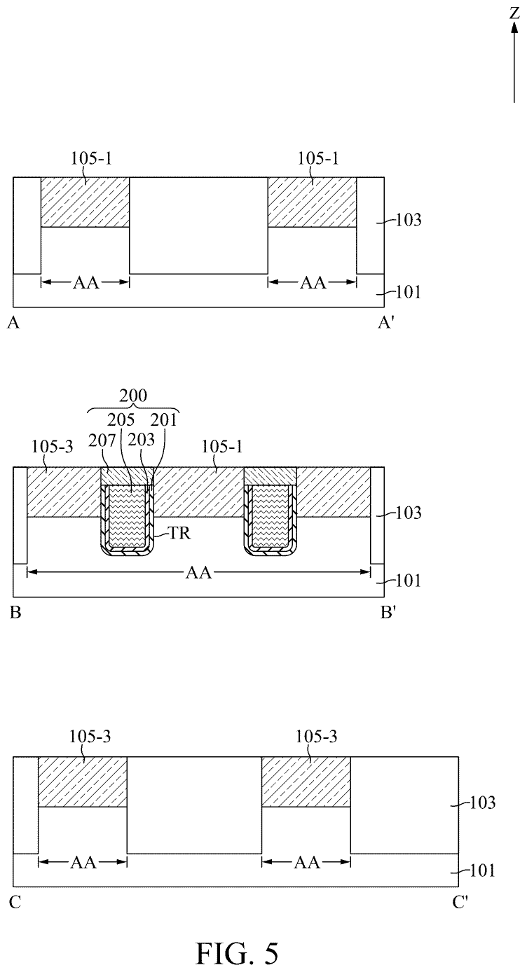

FIG. 1 illustrates, in flowchart diagram form, a method 10 for fabricating a semiconductor device 1A in accordance with one embodiment of the present disclosure. FIG. 2 illustrates, in a schematic top-view diagram, an intermediate semiconductor device in accordance with one embodiment of the present disclosure. FIG. 3 shows schematic cross-sectional view diagrams taken along lines A-A′, B-B′, and C-C′ in FIG. 2. FIG. 4 illustrates, in a schematic top-view diagram, an intermediate semiconductor device in accordance with one embodiment of the present disclosure. FIG. 5 shows schematic cross-sectional view diagrams taken along lines A-A′, B-B′, and C-C′ in FIG. 4.

With reference to FIGS. 1 to 5, in step S11, a substrate 101 may be provided, an isolation layer 103 may be formed in the substrate 101 to define a plurality of active areas AA, and a plurality of word line structures 200 may be formed in the substrate 101 and intersecting the plurality of active areas AA.

With reference to FIGS. 2 and 3, the substrate 101 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or combinations thereof.

In some embodiments, the substrate 101 may include a semiconductor-on-insulator structure consisting of, from bottom to top, a handle substrate, an insulator layer, and a topmost semiconductor material layer. The handle substrate and the topmost semiconductor material layer may be formed of a material same as a material of the bulk semiconductor substrate mentioned above. The insulator layer may be a crystalline or non-crystalline dielectric material such as an oxide and/or a nitride. For example, the insulator layer may be a dielectric oxide such as silicon oxide. For another example, the insulator layer may be a dielectric nitride such as silicon nitride or boron nitride. For yet another example, the insulator layer may comprise a stack of a dielectric oxide and a dielectric nitride such as a stack of, in any order, silicon oxide, silicon nitride, and/or boron nitride. The insulator layer may have a thickness between about 10 nm and about 200 nm. The insulator layer may mitigate current leakage between adjacent elements in the substrate 101 and reduce parasitic capacitance associated with source/drains.

It should be noted that the term “about,” when used to modify a quantity of an ingredient, component, or reactant of the present disclosure, refers to variation in a numerical quantity that can occur, for example, through typical measuring and liquid handling procedures used for making concentrates or solutions. Furthermore, variation can occur from inadvertent error in measuring procedures, differences in manufacture, source, or purity of ingredients employed to make compositions or to carry out methods, and the like. In one aspect, the term “about” means within 10% of the reported numerical value. In another aspect, the term “about” means within 5% of the reported numerical value. In yet another aspect, the term “about” means within 10%, 9%, 8%, 7%, 6%, 5%, 4%, 3%, 2% or 1% of the reported numerical value.

With reference to FIGS. 2 and 3, the isolation layer 103 may be formed in the substrate 101. A series of deposition processes may be performed to deposit a pad oxide layer and a pad nitride layer on the substrate 101. A photolithography process and a subsequent etching process, such as an anisotropic dry etching process, may be performed to form trenches penetrating through the pad oxide layer and the pad nitride layer and extending to the substrate 101. An insulating material may be deposited into the trenches and a planarization process, such as chemical mechanical polishing, may be subsequently performed until a top surface of the substrate 101 is exposed to remove excess deposited material, provide a substantially flat surface for subsequent processing steps, and concurrently form the isolation layer 103. The insulating material may be, for example, silicon oxide or another applicable insulating material. The isolation layer 103 may define the plurality of active areas AA in the substrate 101.

It should be noted that, in the description of the present disclosure, a surface of an element (or a feature) located at a highest vertical level along the Z axis is referred to as a top surface of the element (or the feature). A surface of an element (or a feature) located at a lowest vertical level along the Z axis is referred to as a bottom surface of the element (or the feature).

It should be noted that each of the plurality of active areas AA may comprise a portion of the substrate 101 and a space above the portion of the substrate 101. Describing an element as being disposed on the active area AA means that the element is disposed on a top surface of the portion of the substrate 101. Describing an element as being disposed in the active area AA means that the element is disposed in the portion of the substrate 101; however, a top surface of the element may be even with the top surface of the portion of the substrate 101. Describing an element as being disposed above the first area 10 means that the element is disposed above the top surface of the portion of the substrate 101.

With reference to FIGS. 2 and 3, a plurality of impurity regions 105 may be formed in the plurality of active areas AA, respectively. In some embodiments, the plurality of impurity regions 105 may be formed using an implantation process. In other words, the plurality of impurity regions 105 may be formed by turning portions of the active areas AA into the impurity regions 105. Dopants of the implantation process may include p-type impurities (dopants) or n-type impurities (dopants). P-type impurities may be added to an intrinsic semiconductor to create deficiencies of valence electrons. In a silicon-containing substrate, examples of p-type impurities include but are not limited to boron, aluminum, gallium, and indium. N-type impurities may be added to an intrinsic semiconductor to contribute free electrons to the intrinsic semiconductor. In a silicon-containing substrate, examples of n-type impurities include but are not limited to antimony, arsenic, and phosphorus. In some embodiments, a dopant concentration of the plurality of impurity regions 105 may be between about 1E19 atoms/cm\hat{ }3 and about 1E21 atoms/cm\hat{ }3. After the implantation process is performed, the plurality of impurity regions 105 may have an electrical type such as n-type or p-type.

With reference to FIGS. 4 and 5, a plurality of word line trenches TR may be formed in the substrate 101 to define positions of the plurality of word line structures 200. The plurality of word line trenches TR may be formed using a photolithography process and a subsequent etching process. In some embodiments, from a top-view perspective, the word line trenches TR may have a linear cross-sectional profile, and extend along the direction X and traverse (or intersect) the plurality of impurity regions 105. For example, each impurity region 105 may intersect two word line trenches TR. The plurality of word line trenches TR may divide each of the plurality of impurity regions 105 into a plurality of common source regions 105-1 and a plurality of drain regions 105-3. For one impurity region 105, one common source region 105-1 may be formed between the two word line trenches TR and two drain regions 105-3 may be respectively formed between the isolation layer 103 and the two word line trenches TR.

With reference to FIGS. 4 and 5, the plurality of word line structures 200 (e.g., the two word line structures 200) may be formed in the plurality of word line trenches TR (e.g., the two word line trenches TR), respectively. For brevity, clarity, and convenience of description, only one word line structure 200 is described. The word line structure 200 may include a word line dielectric layer 201, a word line barrier layer 203, a word line conductive layer 205, and a word line capping layer 207.

With reference to FIGS. 4 and 5, the word line dielectric layer 201 may be conformally formed on an inner surface of the word line trench TR. The word line dielectric layer 201 may have a U-shaped cross-sectional profile. In other words, the word line dielectric layer 201 may be inwardly formed in the active area AA. In some embodiments, the word line dielectric layer 201 may be formed using a thermal oxidation process. For example, the word line dielectric layer 201 may be formed through an oxidation process on the inner surface of the word line trench TR. In some embodiments, the word line dielectric layer 201 may be formed using a deposition process such as a chemical vapor deposition or an atomic layer deposition. The word line dielectric layer 201 may include a high-k material, an oxide, a nitride, an oxynitride or a combination thereof. In some embodiments, after a polysilicon liner layer is deposited, the word line dielectric layer 201 may be formed through a radical oxidation on the polysilicon liner layer. In some embodiments, after formation of a silicon nitride liner layer, the word line dielectric layer 201 may be formed through a radical oxidation on the silicon nitride liner layer.

In some embodiments, the high-k material may include a hafnium-containing material. The hafnium-containing material may be, for example, hafnium oxide, hafnium silicon oxide, hafnium silicon oxynitride, or a combination thereof. In some embodiments, the high-k material may be, for example, lanthanum oxide, lanthanum aluminum oxide, zirconium oxide, zirconium silicon oxide, zirconium silicon oxynitride, aluminum oxide, or a combination thereof.

With reference to FIGS. 4 and 5, the word line barrier layer 203 may be conformally formed on the word line dielectric layer 201 and within the word line trench TR. In some embodiments, the word line barrier layer 203 may be formed of, for example, titanium nitride, titanium, or a combination thereof. In some embodiments, the word line barrier layer 203 may be formed of, for example, titanium nitride. In some embodiments, the word line barrier layer 203 may be formed using, for example, an atomic layer deposition, a physical vapor deposition, a chemical vapor deposition, or another applicable deposition processes.

With reference to FIGS. 4 and 5, the word line conductive layer 205 may be formed on the word line barrier layer 203 and within the word line trench TR. In some embodiments, in order to form the word line conductive layer 205, a conductive layer may be formed to fill the word line trench TR, and a recessing process may be subsequently performed. The recessing process may be performed using an etch-back process or sequentially performed using a planarization process and an etch-back process. The word line conductive layer 205 may have a recessed shape that partially fills the word line trench TR. In other words, a top surface of the word line conductive layer 205 may be lower than the top surface of the substrate 101.

In some embodiments, the word line conductive layer 205 may include a metal, a metal nitride, or a combination thereof. For example, the word line conductive layer 205 may be formed of titanium nitride, tungsten, or titanium nitride/tungsten. After the titanium nitride is conformally deposited, a titanium nitride/tungsten structure may be formed, wherein the word line trench TR is partially filled using tungsten. Alternatively, either titanium nitride or tungsten may be used exclusively for the word line conductive layer 205. In some embodiments, the word line conductive layer 205 may be formed of, for example, a conductive material such as doped polycrystalline silicon, doped polycrystalline silicon germanium, or a combination thereof. In some embodiments, the word line conductive layer 205 may be formed of, for example, tungsten, aluminum, titanium, copper, the like, or a combination thereof.

With reference to FIGS. 4 and 5, a dielectric material may be deposited using, for example, a chemical vapor deposition, to completely fill the word line trenches TR and cover the top surface of the substrate 101. A planarization process, such as a chemical mechanical polishing, may be performed to provide a substantially flat surface for subsequent processing steps and to form the word line capping layer 207. In some embodiments, the word line capping layer 207 may be formed of, for example, silicon nitride, or another applicable dielectric material.

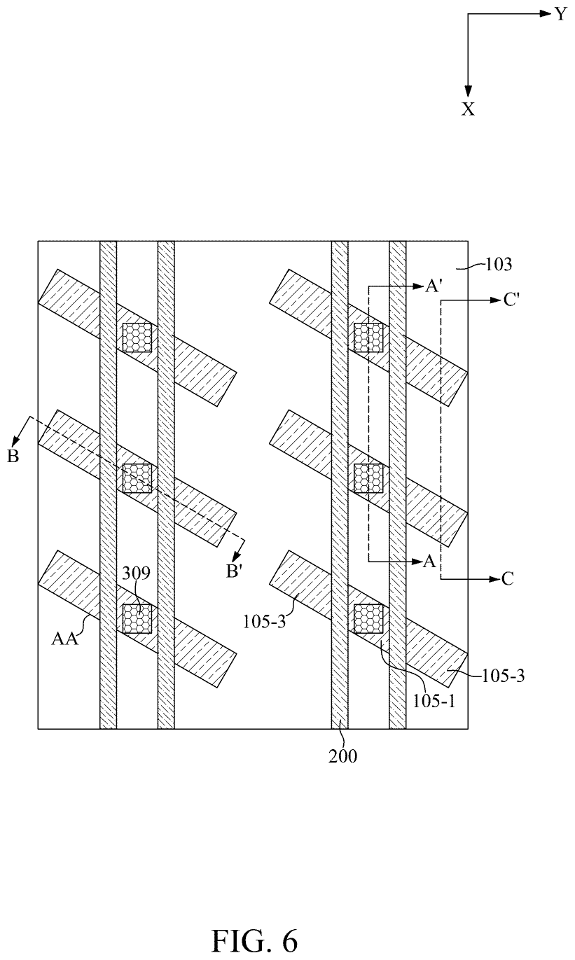

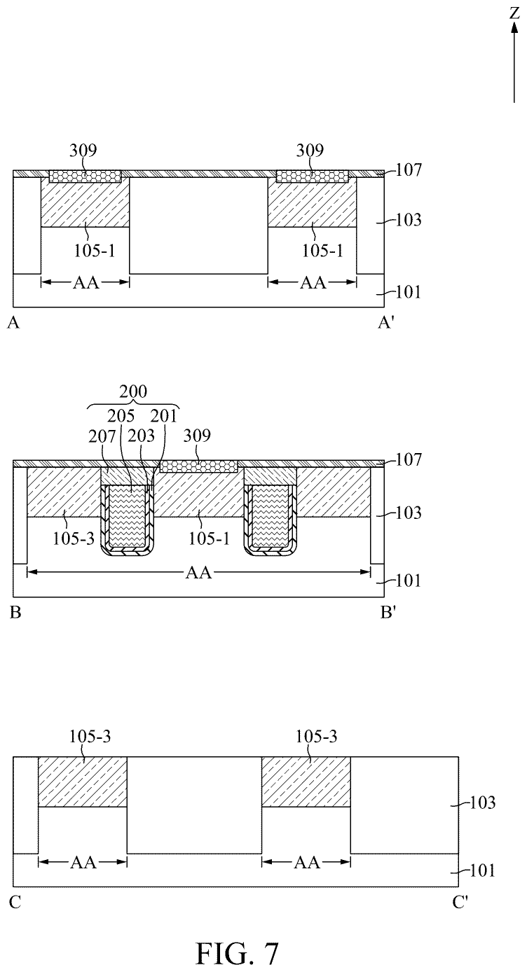

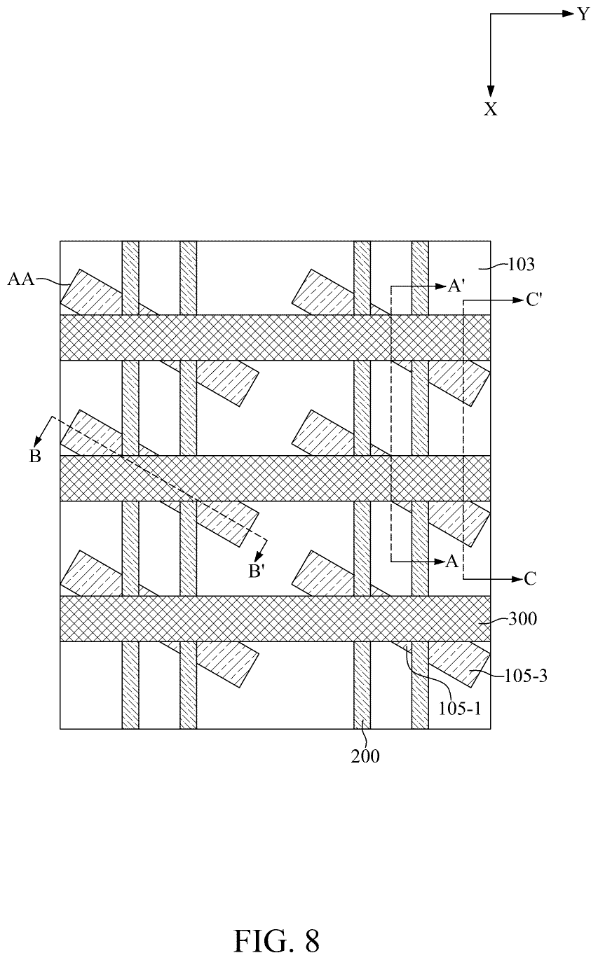

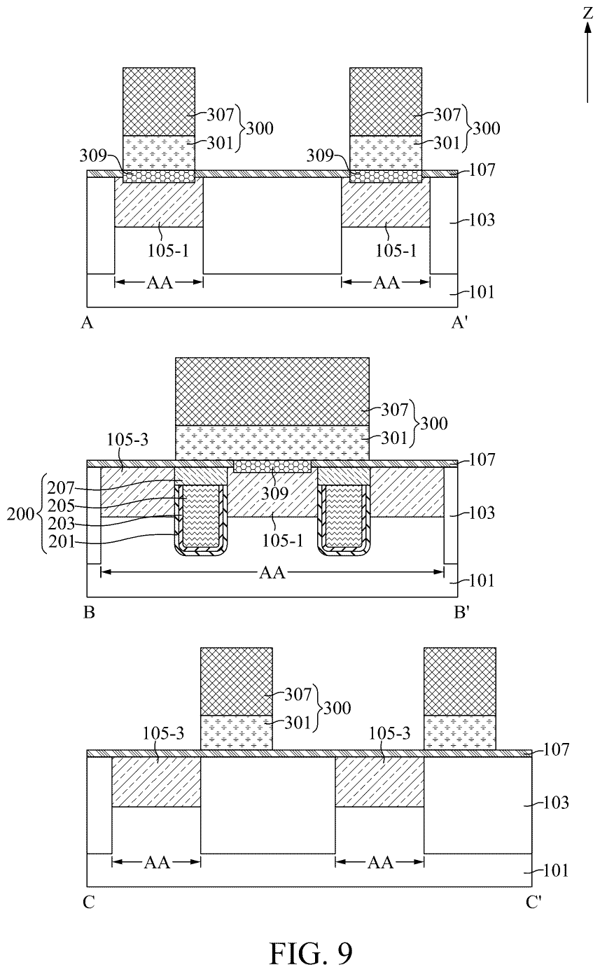

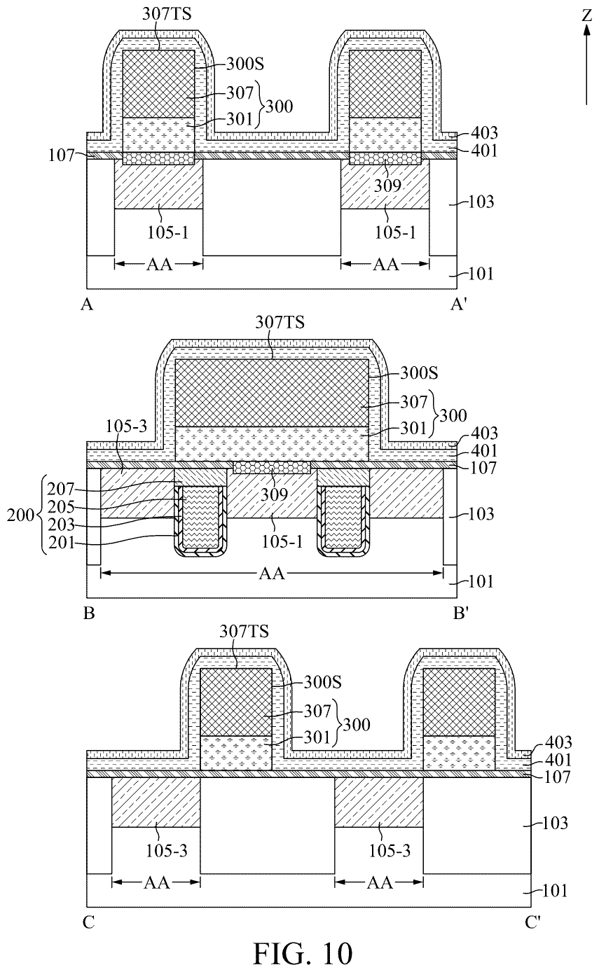

FIG. 6 illustrates, in a schematic top-view diagram, an intermediate semiconductor device in accordance with one embodiment of the present disclosure. FIG. 7 shows schematic cross-sectional view diagrams taken along lines A-A′, B-B′, and C-C′ in FIG. 6. FIG. 8 illustrates, in a schematic top-view diagram, an intermediate semiconductor device in accordance with one embodiment of the present disclosure. FIG. 9 shows schematic cross-sectional view diagrams taken along lines A-A′, B-B′, and C-C′ in FIG. 8 illustrating part of a process flow for fabricating a semiconductor device in accordance with one embodiment of the present disclosure. FIG. 10 shows schematic cross-sectional view diagrams taken along lines A-A′, B-B′, and C-C′ in FIG. 8 illustrating part of a process flow for fabricating a semiconductor device in accordance with one embodiment of the present disclosure.

With reference to FIG. 1 and FIGS. 6 to 10, in step S13, a plurality of bit line structures 300 may be formed on the substrate 101, an inner spacer layer 401 may be conformally formed over the substrate 101, and an outer spacer layer 403 may be conformally formed on the inner spacer layer 401.

With reference to FIGS. 6 and 7, a bottom dielectric layer 107 may be formed on the substrate 101. In some embodiments, the bottom dielectric layer 107 may be formed of a material having etching selectivity with respect to the substrate 101 and the isolation layer 103. In some embodiments, the bottom dielectric layer 107 may be formed of, for example, silicon nitride, boron nitride, silicon boron nitride, phosphorus boron nitride, boron carbon silicon nitride, or a combination thereof. In some embodiments, the bottom dielectric layer 107 may be formed of, for example, silicon nitride. In some embodiments, the bottom dielectric layer 107 may be formed using, for example, a chemical vapor deposition, a plasma-enhanced chemical vapor deposition, or another applicable deposition process.

With reference to FIGS. 6 and 7, a plurality of bit line contacts 309 may be formed to penetrate the bottom dielectric layer 107 and extend to the plurality of common source regions 105-1, respectively. In some embodiments, the plurality of bit line contacts 309 may be formed of, for example, tungsten, cobalt, zirconium, tantalum, titanium, aluminum, ruthenium, copper, metal carbide (e.g., tantalum carbide, titanium carbide, tantalum magnesium carbide), metal nitride (e.g., titanium nitride), transition metal aluminide, or a combination thereof. In some embodiments, from a top-view perspective, the plurality of bit line contacts 309 may have a square-shaped cross-sectional profile, but the disclosure is not limited thereto. In some embodiments, from a top view-perspective, the plurality of bit line contacts 309 may have a rectangle-shaped, a circle-shaped, or another applicable shaped cross-sectional profile.

With reference to FIGS. 8 and 9, the plurality of bit line structures 300 may be formed on the bottom dielectric layer 107 and electrically connected to the plurality of bit line contacts 309, respectively. From a top-view perspective, the plurality of bit line structures 300 may extend along the direction Y and may be separated from each other. In other words, the plurality of bit line structures 300 may intersect the plurality of word line structures 200 in a top-view perspective. For brevity, clarity, and convenience of description, only one bit line structure 300 is described. In some embodiments, the bit line structure 300 may include a bit line top conductive layer 301 and a bit line capping layer 307.

The bit line top conductive layer 301 may be formed on the bit line contact 309 and electrically connected to the bit line contact 309. In some embodiments, the bit line top conductive layer 301 may be formed of, for example, titanium nitride, tungsten, titanium, nickel, platinum, tantalum, cobalt, silver, copper, aluminum, another applicable conductive material, or a combination thereof. The bit line capping layer 307 may be formed on the bit line top conductive layer 301. In some embodiments, the bit line capping layer 307 may be formed of, for example, silicon nitride, or another applicable insulating material.

With reference to FIG. 10, the inner spacer layer 401 may be formed over the substrate 101 to cover the plurality of bit line structures 300 and the bottom dielectric layer 107. Specifically, the inner spacer layer 401 may be conformally formed on the bottom dielectric layer 107 and on sides 300S of the plurality of bit line structures 300 and top surfaces 307TS of the plurality of bit line structures 300. In some embodiments, the inner spacer layer 401 may be formed of, for example, silicon oxide or another applicable insulating oxide. In some embodiments, the inner spacer layer 401 may be formed using, for example, an atomic layer deposition, a chemical vapor deposition, or another applicable deposition process.

With reference to FIG. 10, the outer spacer layer 403 may be conformally formed on the inner spacer layer 401. In some embodiments, the outer spacer layer 403 may be formed of a material same as a material of the bit line capping layer 307. In some embodiments, the outer spacer layer 403 may be formed of, for example, silicon nitride or another applicable insulating material. In some embodiments, the outer spacer layer 403 may be formed using, for example, an atomic layer deposition, a chemical vapor deposition, or another applicable deposition process.

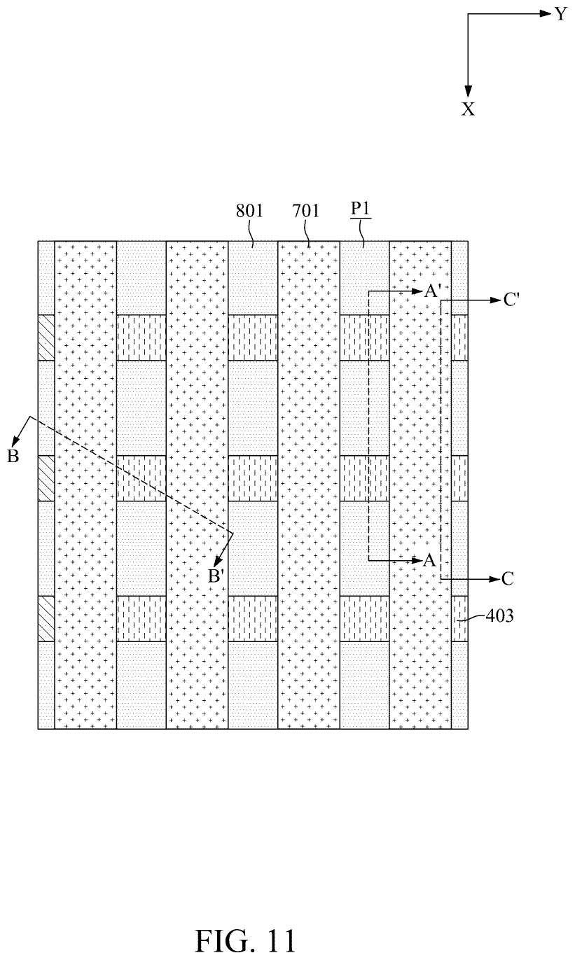

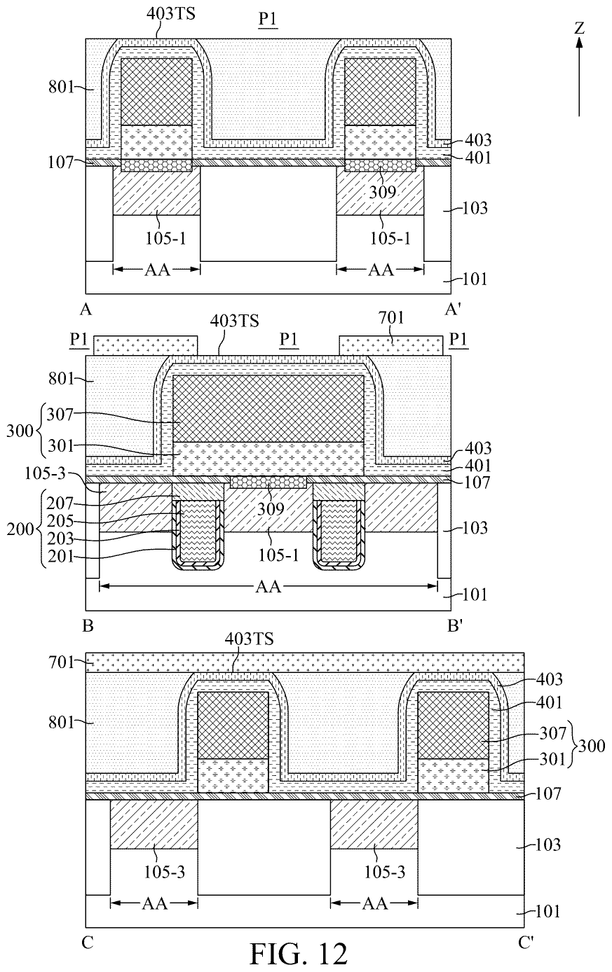

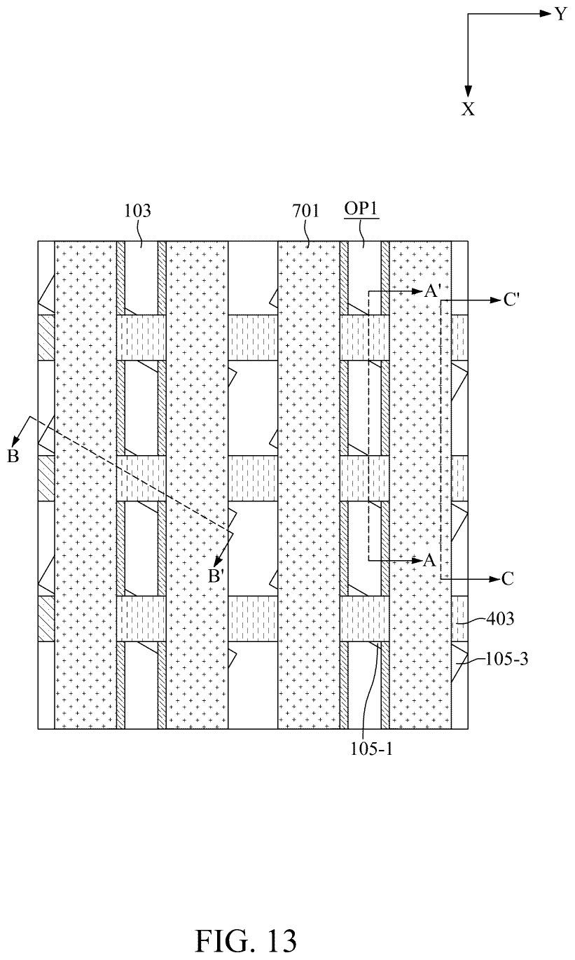

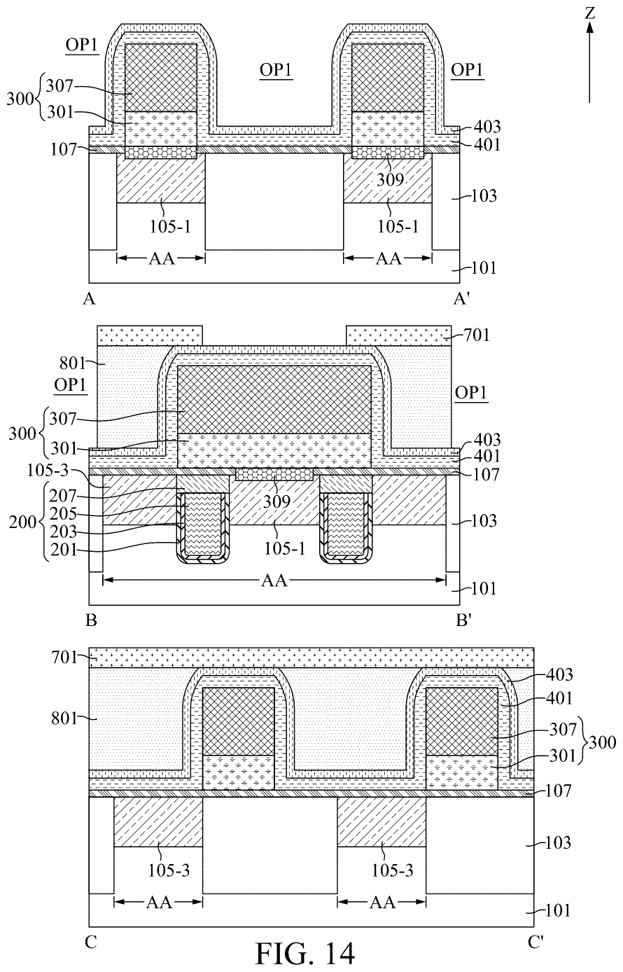

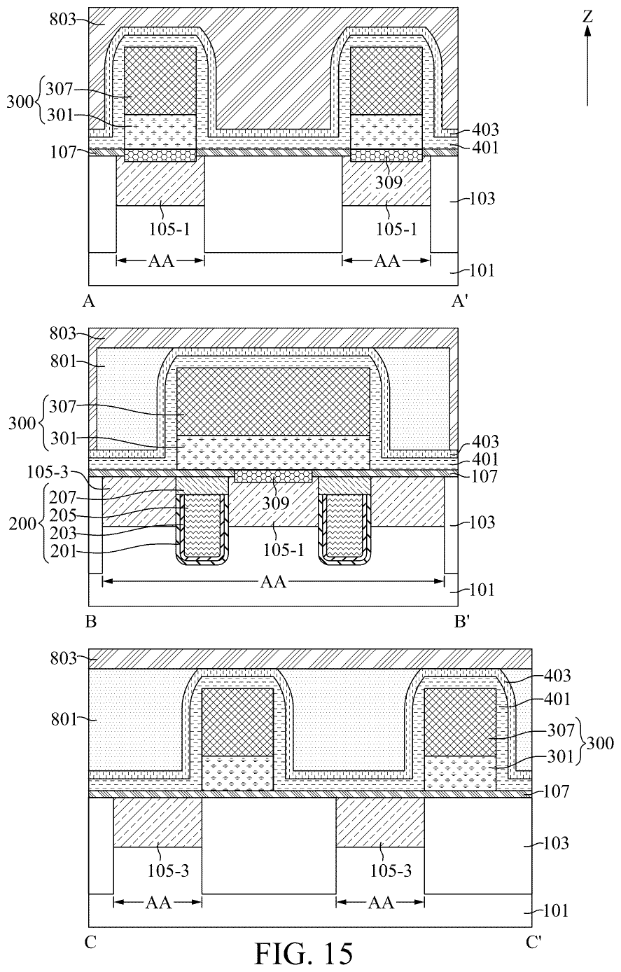

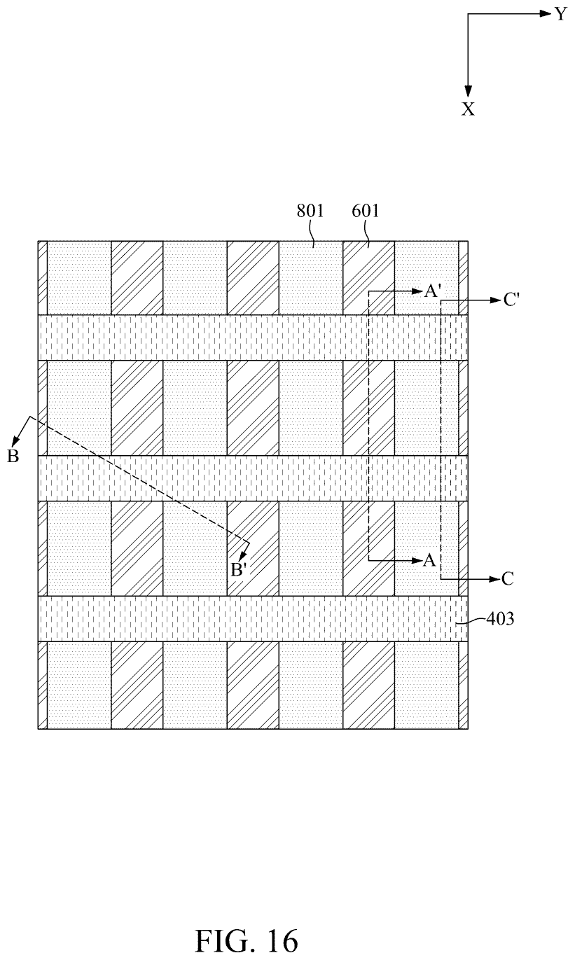

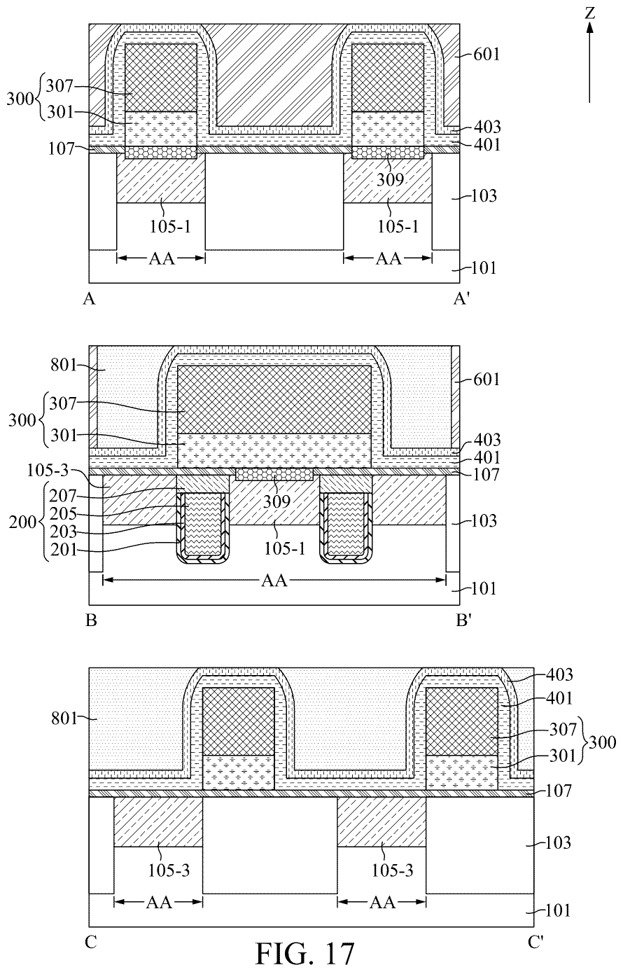

FIG. 11 illustrates, in a schematic top-view diagram, an intermediate semiconductor device in accordance with one embodiment of the present disclosure. FIG. 12 shows schematic cross-sectional view diagrams taken along lines A-A′, B-B′, and C-C′ in FIG. 11. FIG. 13 illustrates, in a schematic top-view diagram, an intermediate semiconductor device in accordance with one embodiment of the present disclosure. FIG. 14 shows schematic cross-sectional view diagrams taken along lines A-A′, B-B′, and C-C′ in FIG. 13 illustrating part of a process for fabricating the semiconductor device 1A in accordance with one embodiment of the present disclosure. FIG. 15 shows schematic cross-sectional view diagrams taken along lines A-A′, B-B′, and C-C′ in FIG. 13 illustrating part of a process for fabricating the semiconductor device 1A in accordance with one embodiment of the present disclosure. FIG. 16 illustrates, in a schematic top-view diagram, an intermediate semiconductor device in accordance with one embodiment of the present disclosure. FIG. 17 shows schematic cross-sectional view diagrams taken along lines A-A′, B-B′, and C-C′ in FIG. 16.

It should be noted that some elements are omitted in top-view diagrams for clarity.

With reference to FIG. 1 and FIGS. 11 to 17, in step S15, a sacrificial layer 801 may be formed among the plurality of bit line structures 300, a first mask layer 701 including a line pattern P1 may be formed on the sacrificial layer 801 to partially expose the sacrificial layer 801 and the outer spacer layer 403, the sacrificial layer 801 may be selectively removed to form a plurality of partition openings OP1, and a plurality of partition layers 601 may be formed in the plurality of partition openings OP1.

With reference to FIGS. 11 and 12, the sacrificial layer 801 may be formed over the bottom dielectric layer 107 to cover the plurality of bit line structures 300, the inner spacer layer 401, and the outer spacer layer 403. In some embodiments, the sacrificial layer 801 may be formed of, for example, a material having etching selectivity with respect to the outer spacer layer 403. In some embodiments, the sacrificial layer 801 may be formed of, for example, silicon oxynitride, silicon nitride oxide, or another applicable material. In some embodiments, the sacrificial layer 801 may be formed using, for example, a chemical vapor deposition, a plasma-enhanced chemical vapor deposition, or another applicable deposition process. In some embodiments, a planarization process, such as a chemical mechanical polishing, may be performed until a surface 403TS of the outer spacer layer 403 is exposed to remove excess material and provide a substantially flat surface for subsequent processing steps.

It should be noted that, in the present disclosure, silicon oxynitride refers to a substance which contains silicon, nitrogen, and oxygen and in which a proportion of oxygen is greater than that of nitrogen. Silicon nitride oxide refers to a substance which contains silicon, oxygen, and nitrogen and in which a proportion of nitrogen is greater than that of oxygen.

With reference to FIGS. 11 and 12, the first mask layer 701 may be formed on the sacrificial layer 801. In some embodiments, the first mask layer 701 may be a photoresist layer. From a top-view perspective, the line pattern P1 of the first mask layer 701 may include multiple rectangular spaces extending in the direction X and arranged alternatively along the direction Y. Through the spaces, the sacrificial layer 801 and the outer spacer layer 403 may be partially exposed.

With reference to FIGS. 13 and 14, the sacrificial layer 801 exposed through the line pattern P1 of the first mask layer 701 may be selectively removed. In some embodiments, the removal of the sacrificial layer 801 may be achieved by an anisotropic etching process, such as an anisotropic dry etching process. After the removal of the sacrificial layer 801, the plurality of partition openings OP1 may be formed in locations where the sacrificial layer 801 was exposed through the line pattern P1 of the first mask layer 701. The first mask layer 701 may be then removed subsequent to the formation of these partition openings OP1.

With reference to FIG. 15, a layer of partition material 803 may be formed over the sacrificial layer 801 to completely fill the plurality of partition openings OP1. In some embodiments, the partition material 803 may be a material having etching selectivity with respect to the sacrificial layer 801. In some embodiments, the partition material 803 may be a material same as materials of the bit line capping layer 307 or the outer spacer layer 403. In some embodiments, the partition material 803 may be, for example, silicon nitride, or another applicable insulating material. In some embodiments, the layer of partition material 803 may be formed using, for example, a chemical vapor deposition or another applicable deposition process.

With reference to FIGS. 16 and 17, a planarization process, such as chemical mechanical polishing, may be performed until the top surface 403TS of the outer spacer layer 403 is exposed to remove excess material, provide a substantially flat surface for subsequent processing steps, and convert the layer of partition material 803 into a plurality of partition layers 601. From a top-view perspective, each of the plurality of partition layers 601 may have a line-shaped (or rectangle-shaped) cross-sectional profile extending along the direction X. The plurality of partition layers 601 may be arranged alternatively along the direction X, with each corresponding bit line structure 300 situated between two adjacent partition layers 601. In the direction Y, the plurality of partition layers 601 may be arranged alternating with the sacrificial layer 801 interposed therebetween. From a top-view perspective, an arrangement of the plurality of partition layers 601 and the plurality of bit line structures 300 may divide the sacrificial layer 801 into multiple segments.

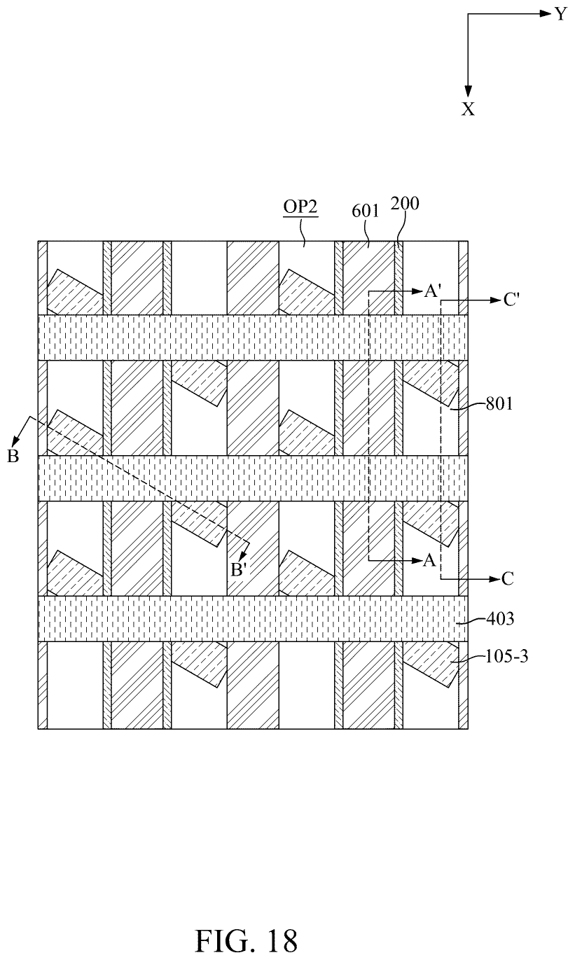

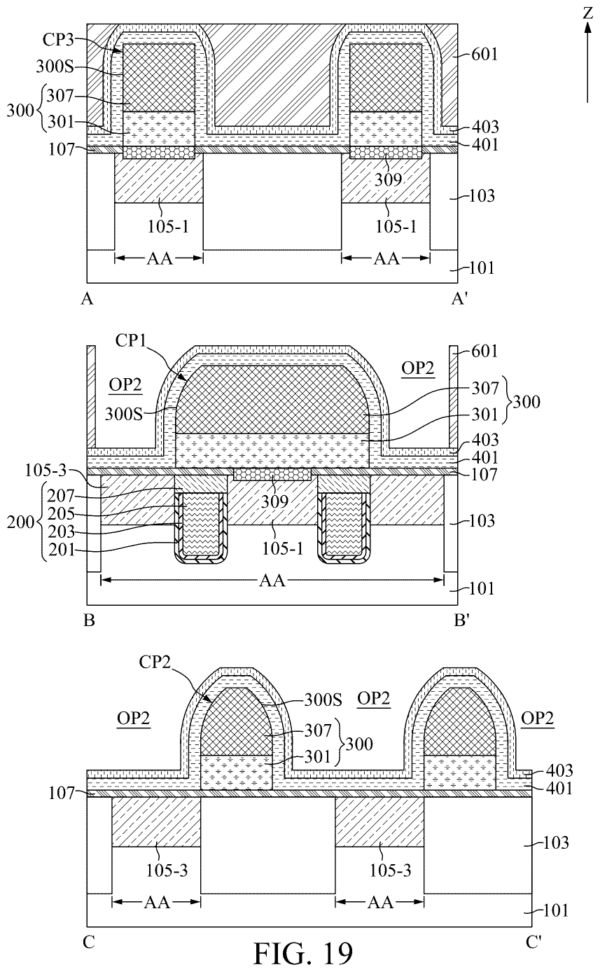

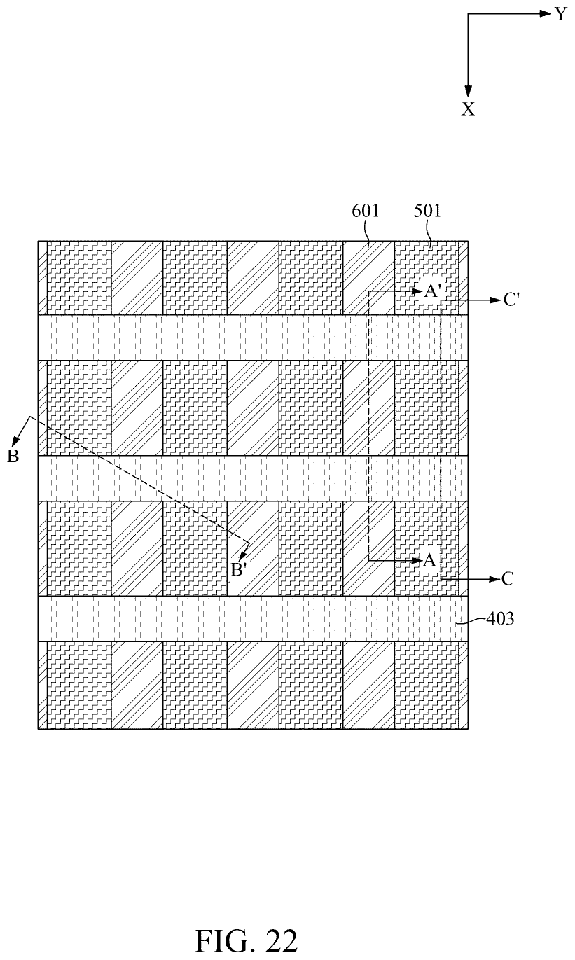

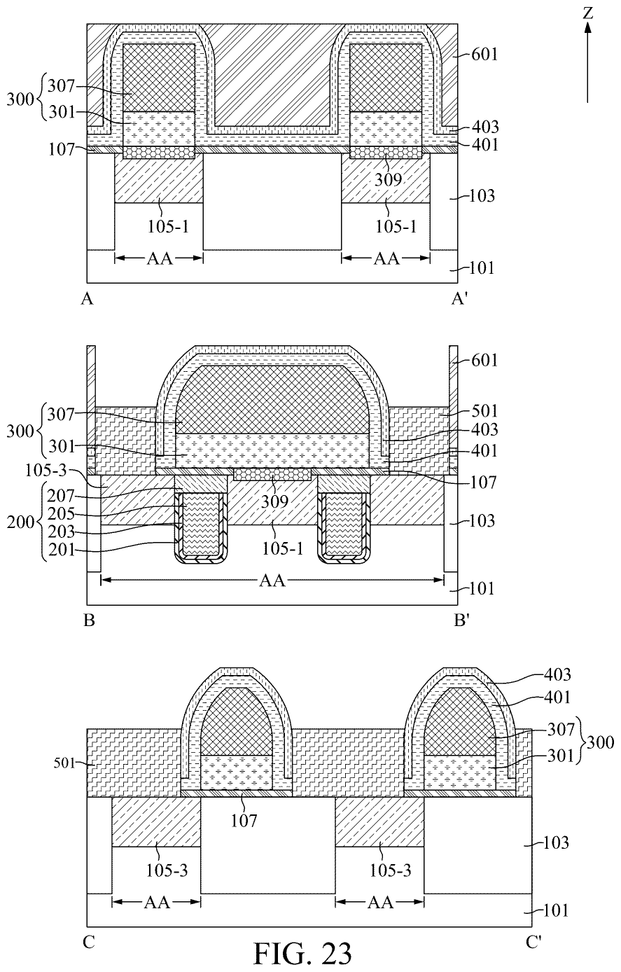

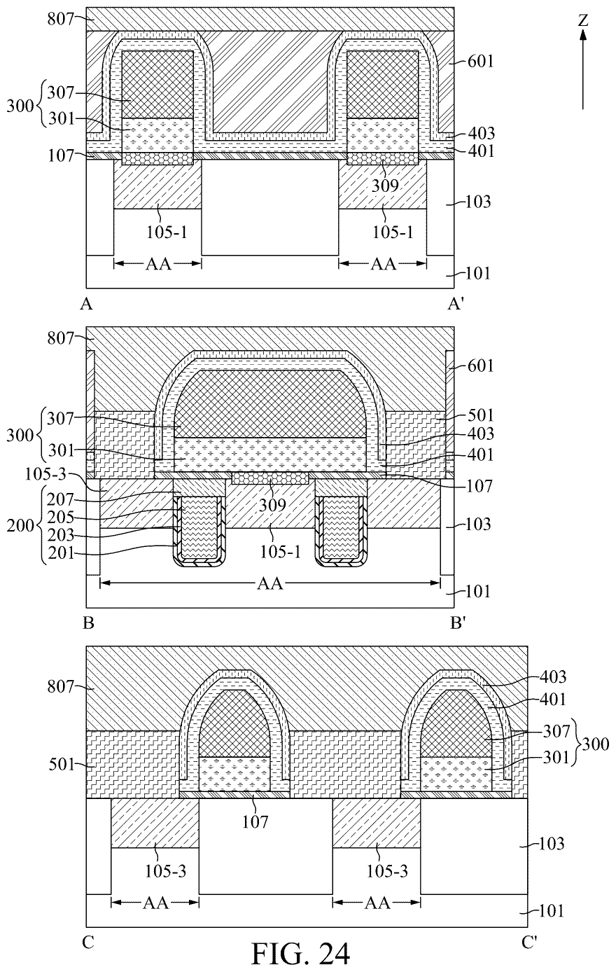

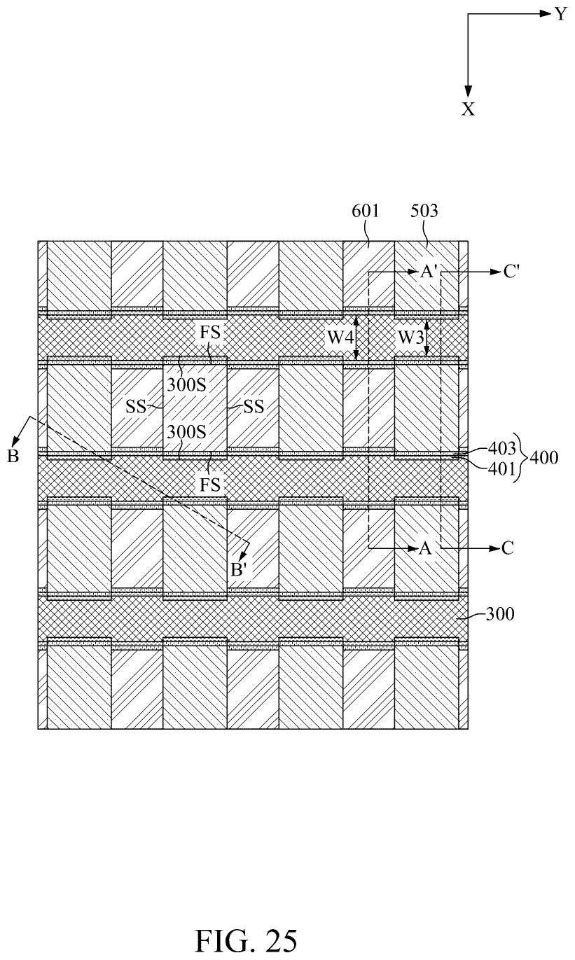

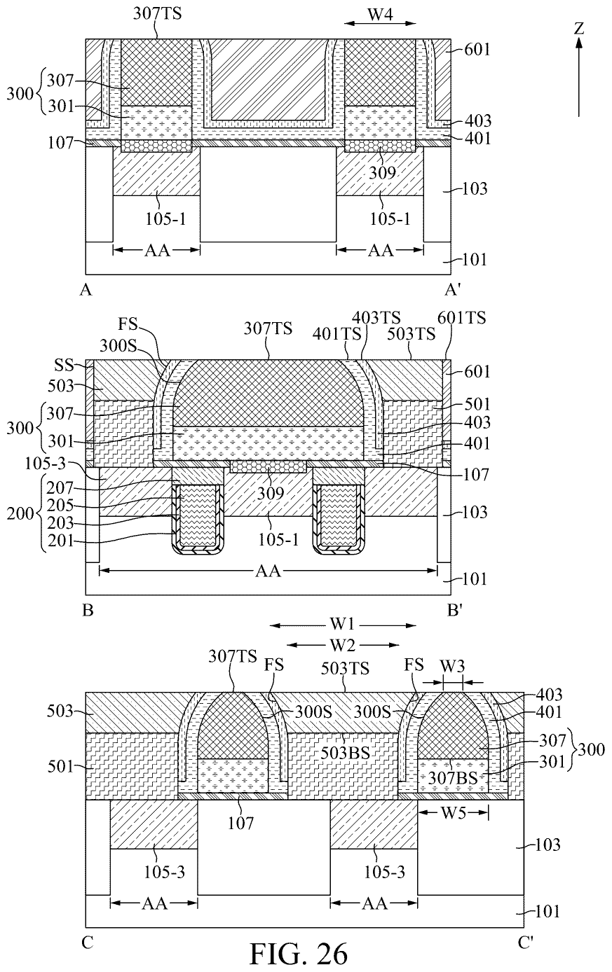

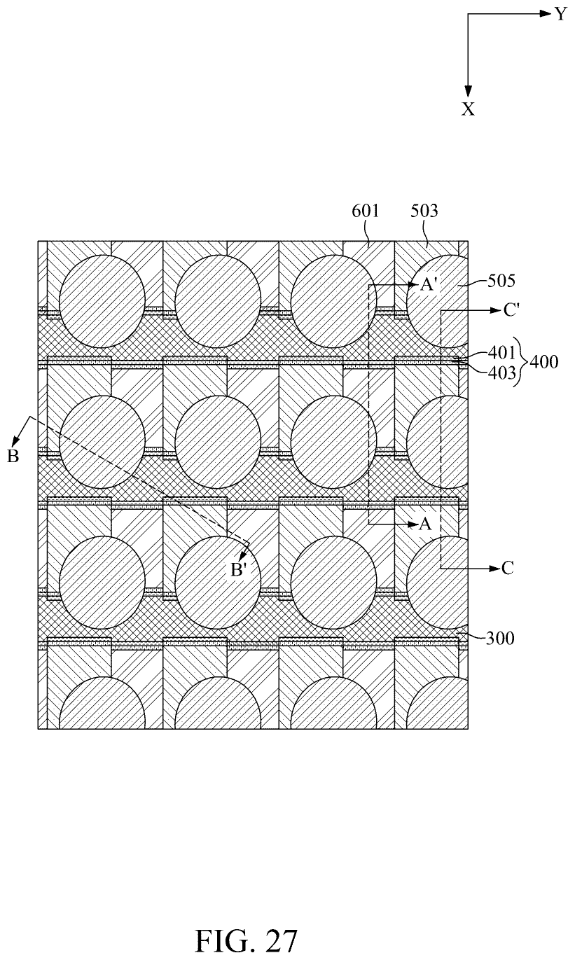

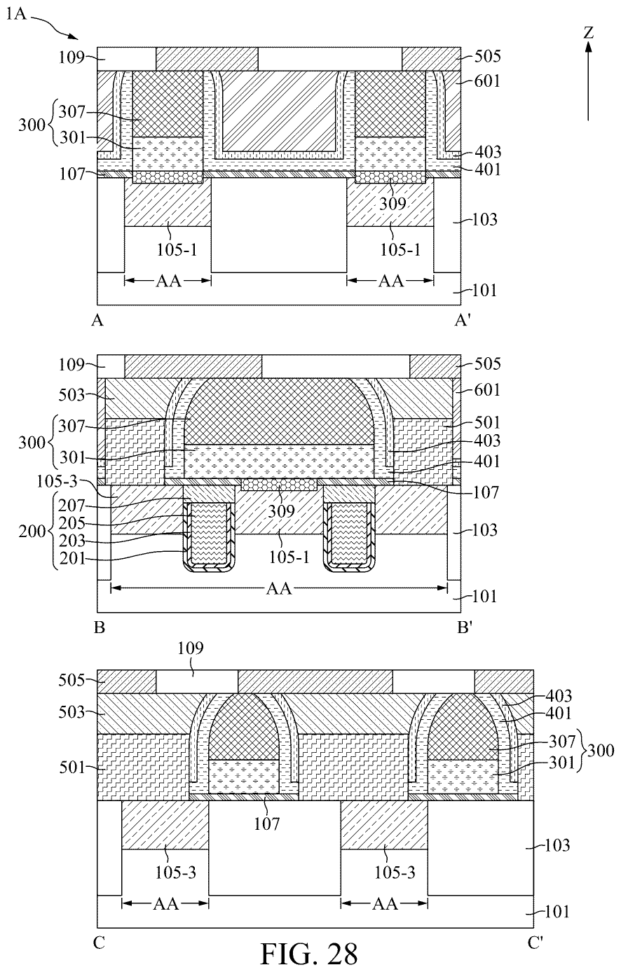

FIG. 18 illustrates, in a schematic top-view diagram, an intermediate semiconductor device in accordance with one embodiment of the present disclosure. Each of FIGS. 19 to 21 shows schematic cross-sectional view diagrams taken along lines A-A′, B-B′, and C-C′ in FIG. 18 illustrating part of a process for fabricating the semiconductor device 1A in accordance with one embodiment of the present disclosure. FIG. 22 illustrates, in a schematic top-view diagram, an intermediate semiconductor device in accordance with one embodiment of the present disclosure. Each of FIGS. 23 and 24 shows schematic cross-sectional view diagrams taken along lines A-A′, B-B′, and C-C′ in FIG. 22 illustrating part of a process for fabricating the semiconductor device 1A in accordance with one embodiment of the present disclosure. FIG. 25 illustrates, in a schematic top-view diagram, an intermediate semiconductor device in accordance with one embodiment of the present disclosure. FIG. 26 shows schematic cross-sectional view diagrams taken along lines A-A′, B-B′, and C-C′ in FIG. 25. FIG. 27 illustrates, in a schematic top-view diagram, an intermediate semiconductor device in accordance with one embodiment of the present disclosure. FIG. 28 shows schematic cross-sectional view diagrams taken along lines A-A′, B-B′, and C-C′ in FIG. 27.

With reference to FIG. 1 and FIGS. 18 to 28, in step S17, the sacrificial layer 801 may be selectively removed to form a plurality of contact openings OP2, a plurality of contact layers 501 may be formed in the plurality of contact openings OP2, a plurality of conductive neck layers 503 may be formed on the plurality of contact layers 501, and a plurality of landing pads 505 may be formed on the plurality of conductive neck layers 503.

With reference to FIGS. 18 and 19, the sacrificial layer 801 may be selectively removed using an etching process. For example, removal of the sacrificial layer 801 may be achieved through an anisotropic etching process. After the removal of the sacrificial layer 801, the plurality of contact openings OP2 may be formed in the locations previously occupied by multiple segments of the sacrificial layer 801. For brevity, clarity, and convenience of description, only one contact opening OP2 is described. From a cross-sectional perspective, the contact opening OP2 may be disposed on the bottom dielectric layer 107. From a top-view perspective, the contact opening OP2 may be enclosed by two adjacent partition layers 601 in the direction Y and two adjacent bit line structures 300 (with the inner spacer layer 401 and the outer spacer layer 403 disposed therebetween) in the direction X.

In some embodiments, during the anisotropic etching process, an etching selectivity of silicon oxide may be similar to an etching selectivity of silicon nitride. In some embodiments, the etching selectivity of silicon oxide may be slightly greater than the etching selectivity of silicon nitride. For example, during the anisotropic etching process, an etch rate ratio of silicon oxide to silicon nitride may be between about 3.0 and about 1.1, between about 2.0 and about 1.1, or between about 1.5 and about 1.2. Due to this comparable etching rate of both silicon oxide and silicon nitride, the inner spacer layer 401, the outer spacer layer 403, and the bit line capping layer 307 may also be partially consumed during the removal of the sacrificial layer 801.

In some embodiments, the inner spacer layer 401, the outer spacer layer 403, and the bit line capping layer 307 adjacent to the sacrificial layer 801 may be the first to be consumed. As a result, during the anisotropic etching process, upper parts of the outer spacer layer 403, the inner spacer layer 401, and the bit line capping layer 307 adjacent to the plurality of contact openings OP2 may become thinner, resulting in a tapered cross-sectional profile and slanted sides 300S in these areas, as indicated by the arrows CP1 and CP2.

In some embodiments, the outer spacer layer 403, the inner spacer layer 401, and the bit line capping layer 307 adjacent to the plurality of partition layers 601 may undergo less consumption than those adjacent to the plurality of contact openings OP2. As a result, the outer spacer layer 403, the inner spacer layer 401, and the bit line capping layer 307 adjacent to the plurality of partition layers 601 may retain a rectangular cross-sectional profile and vertical sides 300S, as indicated by the arrow CP3.

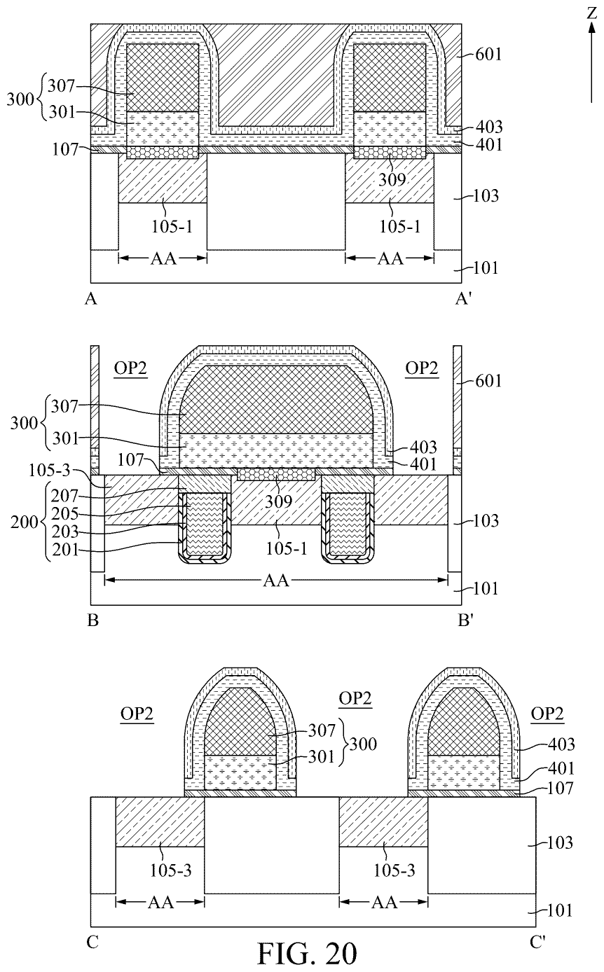

With reference to FIG. 20, a punch-through etching process may be performed to remove parts of the outer spacer layer 403, the inner spacer layer 401, and the bottom dielectric layer 107 that are exposed through the plurality of contact openings OP2. In some embodiments, the punch-through etching process may be an anisotropic dry etching process. The punch-through etching process may extend the plurality of contact openings OP2 downward to the substrate 101. The punch-through etching process may segment the bottom dielectric layer 107, the inner spacer layer 401, and the outer spacer layer 403 into multiple parts, respectively. After the punch-through etching process, the plurality of drain regions 105-3 may be exposed through the plurality of contact openings OP2.

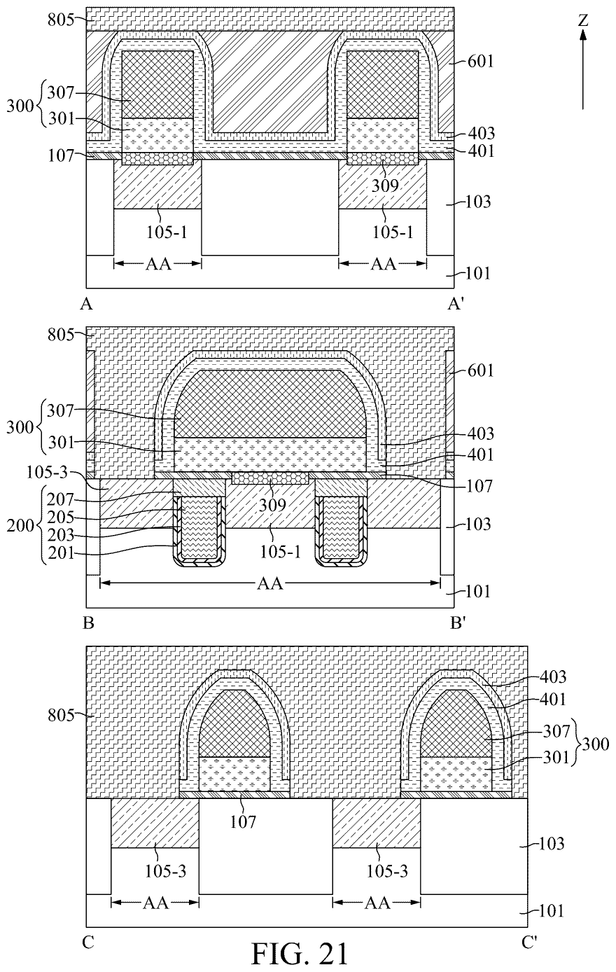

With reference to FIG. 21, a layer of first conductive material 805 may be conformally formed to fill the plurality of contact openings OP2. In some embodiments, the first conductive material 805 may be, for example, doped polycrystalline silicon, doped polycrystalline germanium, or doped polycrystalline silicon germanium. In some embodiments, the first conductive material 805 may include p-type dopants or n-type dopants. In some embodiments, the layer of first conductive material 805 may be formed using, for example, an atomic layer deposition, a chemical vapor deposition, or another applicable deposition process.

With reference to FIGS. 22 and 23, an etch-back process may be performed to remove portions of the first conductive material 805. After the etch-back process is performed, remaining first conductive material 805 may be turned into a plurality of contact layers 501 within the plurality of contact openings OP2. For brevity, clarity, and convenience of description, only one contact layer 501 is described. In some embodiments, from a top-view perspective, the contact layer 501 may exhibit a square or rectangular cross-sectional profile. The contact layer 501 is enclosed by two adjacent partition layers 601 in the direction Y and two adjacent bit line structures 300 (with the inner spacer layer 401 and the outer spacer layer 403 disposed in between) in the direction X. The contact layer 501 provides an electrical connection to the corresponding drain region 105-3.

With reference to FIG. 24, a layer of second conductive material 807 may be deposited to completely fill the plurality of contact openings OP2 and cover the outer spacer layer 403, the inner spacer layer 401, the plurality of bit line structures 300, and the plurality of partition layers 601. In some embodiments, the second conductive material 807 may include materials such as, for example, tungsten, cobalt, zirconium, tantalum, titanium, aluminum, ruthenium, copper, metal carbide (e.g., tantalum carbide, titanium carbide, tantalum magnesium carbide), metal nitride (e.g., titanium nitride), transition metal aluminides, or a combination thereof. In some embodiments, the second conductive material 807 may be, for example, titanium nitride, titanium, tungsten, or a combination thereof.

With reference to FIGS. 25 and 26, a planarization process, such as chemical mechanical polishing, may be performed until the top surfaces 307TS of the plurality of bit line capping layers 307 are exposed to remove excess material and provide a substantially flat surface for subsequent processing steps. After the planarization process is performed, remaining second conductive material 807 may be turned into the plurality of conductive neck layers 503. The plurality of conductive neck layers 503 may be formed on the plurality of contact layers 501.

For brevity, clarity, and convenience of description, only one conductive neck layer 503 is described. In some embodiments, from a top-view perspective, the conductive neck layer 503 is enclosed by two adjacent partition layers 601 in the direction Y and two adjacent bit line structures 300 (with the inner spacer layer 401 and the outer spacer layer 403 disposed in between) in the direction X. In some embodiments, a width W1 of the top surface 503TS of the conductive neck layer 503 may be greater than a width W2 of the bottom surface 503BS of the conductive neck layer 503. In some embodiments, a ratio of the width W1 of the top surface 503TS of the conductive neck layer 503 to the width W2 of the bottom surface 503BS of the conductive neck layer 503 may be between about 2.0 and about 1.3, between about 1.8 and about 1.3, and between about 1.7 and about 1.4.

In some embodiments, the conductive neck layer 503 may include two first sides FS. The two first sides FS may contact the sides 300S of the corresponding adjacent pair of the bit line structures 300 with the inner spacer layer 401 and the outer spacer layer 403 disposed in between. Specifically, the inner spacer layer 401 may be disposed between the bit line structure 300 and the conductive neck layer 503, while the outer spacer layer 403 may be disposed between the inner spacer layer 401 and the conductive neck layer 503. In some embodiments, the two first sides FS may be slanted due to conforming to the profile of the outer spacer layer 403. The slanted first sides FS may make the conductive neck layer 503 exhibit a tapered cross-sectional profile towards the contact layer 501. In some embodiments, the conductive neck layer 503 may include two second sides SS. The two second sides SS may contact the corresponding partition layers 601. In some embodiments, the two second sides SS may be vertical in relation to the first sides FS.

In some embodiments, a width W3 of the top surface 307TS of the bit line capping layer 307 adjacent to the conductive neck layers 503 may be narrower than a width W4 of the top surface 307TS of the bit line capping layer 307 adjacent to the partition layers 601. Consequently, from a top-view perspective, the width W3, W4 of the top surface 307TS of the bit line structure 300 may vary in the direction Y.

In some embodiments, the width W3 of the top surface 307TS of the bit line capping layer 307 adjacent to the conductive neck layers 503 may be narrower than a width W5 of the bottom surface 307BS of the bit line capping layer 307.

In some embodiments, the top surface 307TS of the bit line structure 300, the top surface 401TS of the inner spacer layer 401, the top surface 403TS of the outer spacer layer 403, the top surface 503TS of the conductive neck layer 503, and the top surface 601TS of the partition layer 601 may be substantially coplanar.

With reference to FIGS. 27 and 28, a top dielectric layer 109 may be formed over the substrate 101 to completely cover the plurality of partition layers 601, the plurality of inner spacer layers 401, the plurality of outer spacer layers 403, the plurality of conductive neck layers 503, and the plurality of bit line structures 300. In some embodiments, the top dielectric layer 109 may be formed of, for example, silicon dioxide, undoped silicate glass, fluorosilicate glass, borophosphosilicate glass, a spin coating low k dielectric layer, a chemical vapor deposition low-k dielectric layer, or a combination thereof. The term “low k” as used throughout the present application denotes a dielectric material that has a dielectric constant of less than silicon dioxide. In some embodiments, the top dielectric layer 109 may include a self-planarizing material such as a spin coating glass or a spin coating low-k dielectric material such as SiLK™. The use of a self-planarizing dielectric material may avoid the need to perform a subsequent planarizing step. In some embodiments, the top dielectric layer 109 may be formed using a deposition process including, for example, a chemical vapor deposition, a plasma enhanced chemical vapor deposition, an evaporation, or a spin coating.

With reference to FIGS. 27 and 28, the plurality of landing pads 505 may be formed penetrating the top dielectric layer 109. The plurality of landing pads 505 may be formed on the plurality of conductive neck layers 503, respectively. For brevity, clarity, and convenience of description, only one landing pad 505 is described. In some embodiments, from a top-view perspective, the landing pad 505 may partially overlap the conductive neck layer 503. In some embodiments, the landing pad 505 may be formed of a material same as a material of the conductive neck layer 503. In some embodiments, the landing pad 505 may be formed of, for example, tungsten, cobalt, zirconium, tantalum, titanium, aluminum, ruthenium, copper, metal carbide (e.g., tantalum carbide, titanium carbide, tantalum magnesium carbide), metal nitride (e.g., titanium nitride), transition metal aluminides, or a combination thereof.

By utilizing a wider top surface 503TS of the conductive neck layer 503, overlapping window for the conductive neck layer 503 and the landing pad 505 may be increased. This enhancement can lead to a reduction in defects (e.g., overlay misalignment) and decrease complexity for fabricating the semiconductor device 1A.

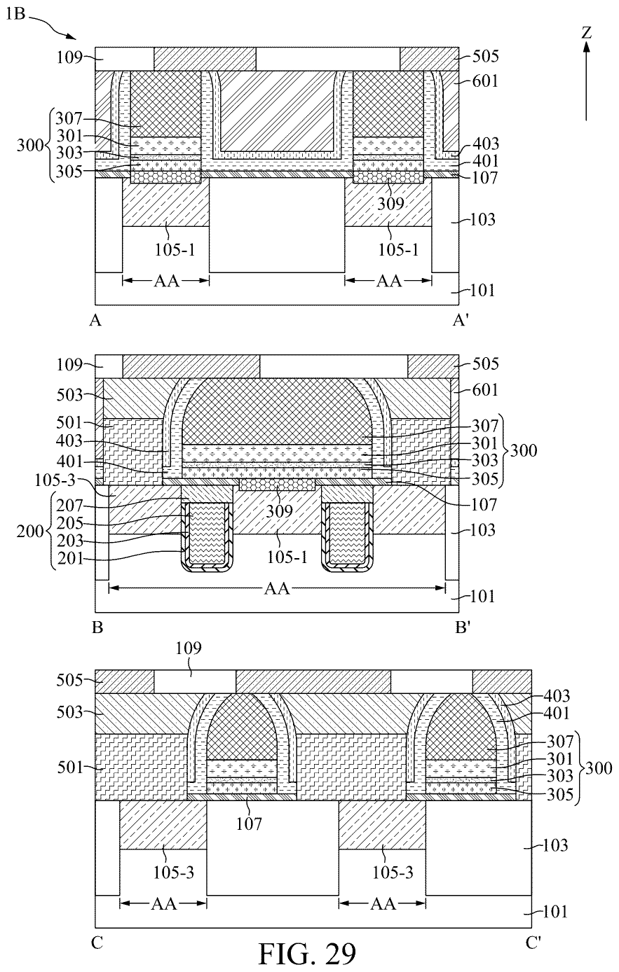

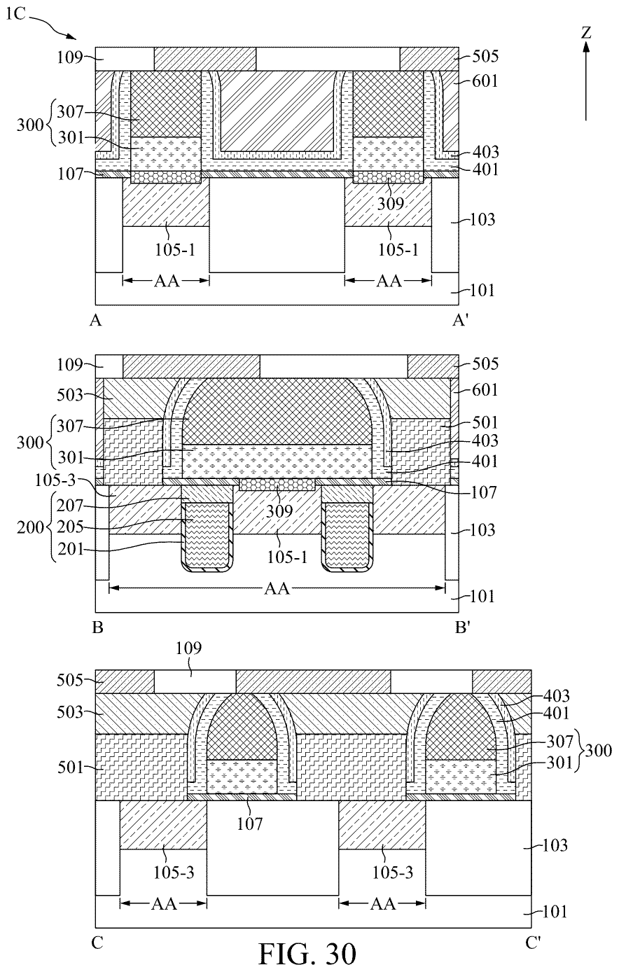

FIGS. 29 and 30 illustrate, in schematic cross-sectional view diagrams, semiconductor devices 1B and 1C in accordance with some embodiments of the present disclosure.

With reference to FIG. 29, the semiconductor device 1B may have a structure similar to that illustrated in FIG. 28. Elements in FIG. 29 that are same as or similar to elements in FIG. 28 are marked with similar reference numbers and duplicative descriptions are omitted.

In semiconductor device 1B, the bit line structure 300 may include a bit line bottom conductive layer 305, a bit line middle conductive layer 303, a bit line top conductive layer 301, and a bit line capping layer 307.

The bit line bottom conductive layer 305 may be disposed on the bit line contact 309. In some embodiments, the bit line bottom conductive layer 305 may be formed of, for example, doped polycrystalline silicon, doped polycrystalline germanium, doped polycrystalline silicon germanium, or a combination thereof. In some embodiments, the dopants for the bottom conductive layer 305 may include boron, aluminum, gallium, indium, antimony, arsenic, or phosphorus.

The bit line middle conductive layer 303 may be disposed on the bit line bottom conductive layer 305. In some embodiments, the bit line middle conductive layer 303 may be formed of, for example, titanium silicide, nickel silicide, nickel platinum silicide, tantalum silicide, or cobalt silicide. In some embodiments, the bit line middle conductive layer 303 may have a thickness between about 2 nm and about 20 nm.

The bit line top conductive layer 301 may be disposed on the bit line middle conductive layer 303. In some embodiments, the bit line top conductive layer 301 may be formed of, for example, titanium, nickel, platinum, tantalum, cobalt, silver, copper, aluminum, another applicable conductive material, or a combination thereof.

The bit line capping layer 307 may be disposed on the bit line top conductive layer 301. In some embodiments, the bit line capping layer 307 may be formed of, for example, silicon nitride or another applicable insulating material.

With reference to FIG. 30, the semiconductor device 1C may have a structure similar to that illustrated in FIG. 28. Elements in FIG. 20 that are same as or similar to elements in FIG. 28 are marked with similar reference numbers and duplicative descriptions are omitted.

In the semiconductor device 1C, there is no word line barrier layer 203 as shown in the FIG. 28. The word line conductive layer 205 may be directly disposed on the word line dielectric layer 201. In the present embodiment, the word line conductive layer 205 may be formed of titanium nitride.

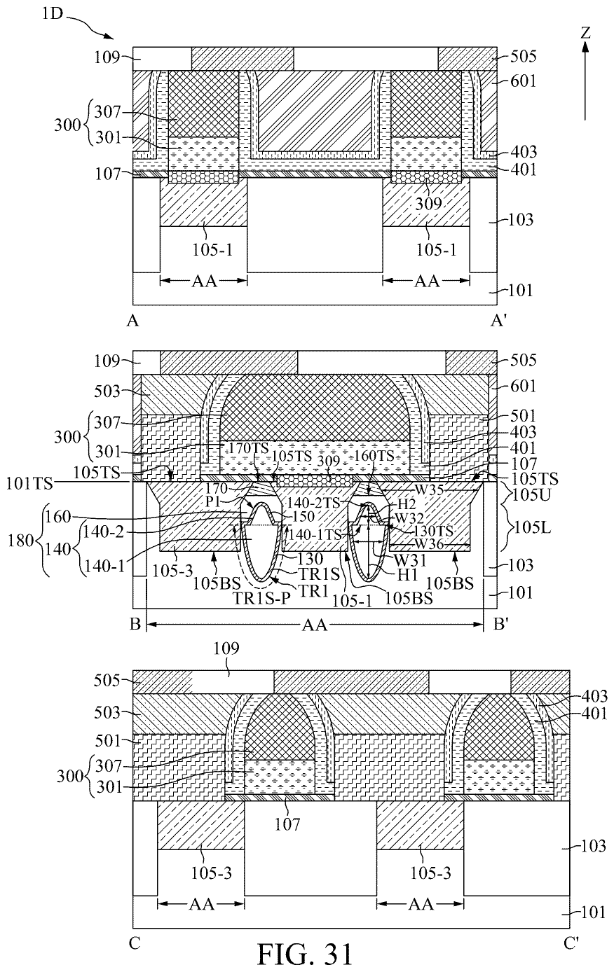

FIG. 31 is a schematic cross-sectional diagram of a semiconductor device 1D taken along the line B-B′ in FIG. 27 in accordance with another embodiment of the present disclosure. The semiconductor device 1D is similar to the intermediate semiconductor structure in FIG. 28, expect that the semiconductor device 1D comprises a buried gate electrode 180 and an impurity region 105-1/105-3 in the active region AA.

It should be noted that schematic cross-sectional diagrams of the semiconductor device 1D taken along the line A-A′ and C-C′ are same as those of the intermediate semiconductor structure in FIG. 27, and repeated diagram and descriptions are omitted

With reference to FIG. 31, in some embodiments, the buried gate electrode 180 may be disposed within a trench TR1 in the substrate 101. The active region AA includes a first impurity region 105-1 and a second impurity region 105-3. The first impurity region 105-1 and the second impurity region 105-3 are divided by the gate trench TR1.

As shown in FIG. 30, a first gate material 140 is disposed on a portion TR1S-P of a sidewall TR1S of the gate trench TR1. The first gate material 140 includes a first member 140-1 and a second member 140-2 on the first member 140-1. The second member 140-2 is a protruding member extending from the first member 140-1 toward the top surface 101TS of the substrate 101. The first member 140-1 and the second member 140-2 have different diameters and different heights. In some embodiments, the second member 140-2 has a dome shape. In some embodiments, the first member 140-1 has a first width W31 that varies at different vertical levels and a first height H1, and the second member 140-2 has a second width W32 that varies at different vertical levels and a second height H2.

The first member 140-1 is surrounded by a first barrier layer 130. Moreover, the first member 140-1 and the second member 140-2 are covered by a second barrier layer 150. As a result, the first gate material 140 is completely encased by the first barrier layer 130 and the second barrier layer 150. In some embodiments, the first barrier layer 130 and the second barrier layer 150 are integrally formed. A second gate material 160 is disposed at a middle portion of the gate trench TR1 and covers the first gate material 140. The second barrier layer 150 is interposed between the second gate material 160 and the first gate material 140. A gate insulating material 170 is disposed at an upper portion of the gate trench TR1 and covers the second gate material 160.

In some embodiments, the first barrier layer 130 and the second barrier layer 150 include various materials such as tantalum (Ta), titanium (Ti), tantalum nitride (TaN), titanium nitride (TiN), titanium silicon nitride (TiSiN), or other suitable materials. The gate insulating material 170 includes silicon nitride (Si3N4) or other suitable materials. The first gate material 140 includes various metals such as aluminum (Al), copper (Cu), tungsten (W), titanium (Ti), or other suitable materials. The second gate material 160 includes doped or undoped polycrystalline silicon. The first gate material 140 is used as a metal gate electrode and the second gate material 160 is used as a polysilicon gate electrode. In some embodiments, the first gate material 140 and the second gate material 160 within the gate trench TR1 together form the buried gate electrode 180 in the active region AA. In some embodiments, the buried gate electrode 180, the first barrier layer 130, the second barrier layer 150, and the gate insulating material 170 together form a buried gate structure.

In the buried gate electrode 180, the second member 140-2 of the first gate material 140 extends toward the second gate material 160. The buried gate electrode 180 (or the buried gate structure), the first impurity region 105-1 and the second impurity region 105-3 together form a transistor of a DRAM device.

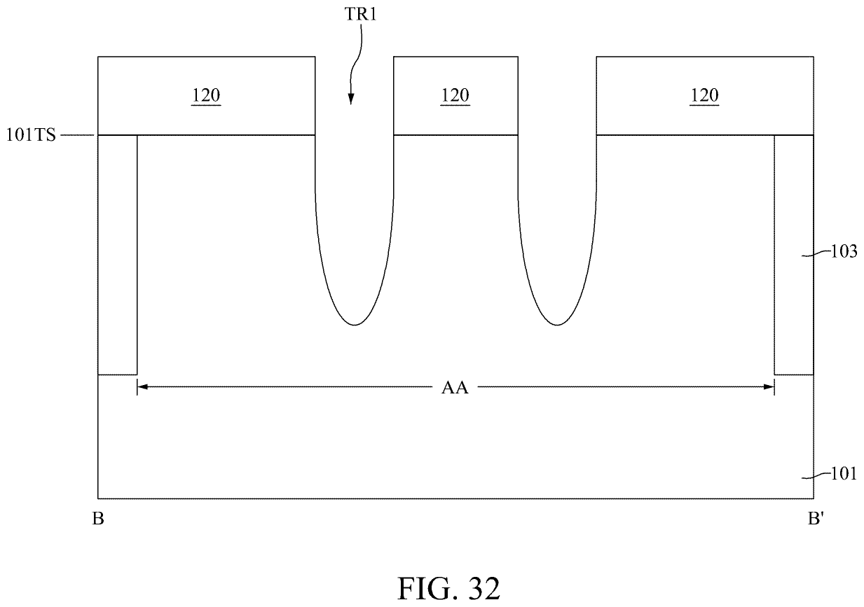

FIGS. 32 to 42 are schematic cross-sectional diagrams taken along the line B-B′ in FIG. 27 illustrating part of a process for fabricating a semiconductor device 1D in accordance with another embodiment of the present disclosure. The corresponding step is illustrated in step S11 of the method 10 shown in FIG. 1.

With reference to FIG. 32, a gate trench formation process is performed on a substrate 101 with an isolation region 103. In some embodiments, the gate trench formation process is a recess formation process. First, referring to FIG. 32, a photoresist pattern 120 is formed on the substrate 101 to define a location of a recess. In some embodiments, the photoresist pattern 120 includes multiple openings exposing a top surface 101TS of the substrate 101. Specifically, the formation of the photoresist pattern 120 includes sequentially coating a photoresist layer on an active region AA and the isolation region 103, exposing the photoresist layer to radiation using a photomask and a lithographic process, and developing the exposed photoresist layer.

Next, the active region AA is etched using the photoresist pattern 120 as an etching mask. Portions of the active region AA exposed by the openings are removed. Therefore, multiple gate trenches TR1 are formed in the active region AA, and the photoresist pattern 120 is then removed using an ashing process or a wet strip process. In some embodiments, a depth of the gate trench TR1 is less than a depth of the isolation region 103.

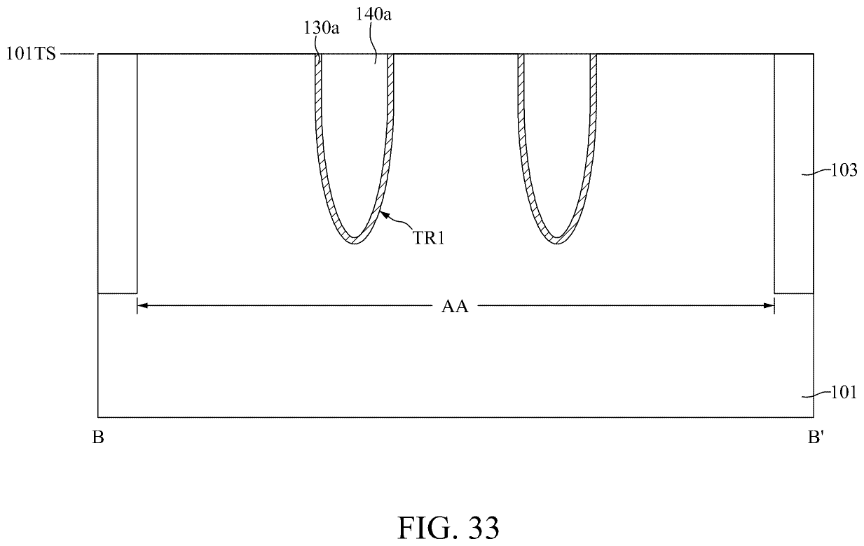

With reference to FIG. 33, a first barrier layer 130a is formed on the substrate 101. Specifically, first, the first barrier layer 130a is deposited over the active region AA and the isolation region 103 and conformally formed within the gate trench TR1. Next, a CMP process is performed to remove portions of the first barrier layer 130a over the top surface 101TS of the substrate 101. As a result, remaining portions of the first barrier layer 130a line inner sidewalls of the gate trenches TR1. In some embodiments, the first barrier layer 130a is formed using a CVD process. Preferably, the first barrier layer 130a is formed using an atomic layer deposition (ALD) process to allow formation of a highly conformal barrier layer having a more uniform thickness. In some embodiments, the first barrier layer 130a includes various materials such as tantalum (Ta), titanium (Ti), tantalum nitride (TaN), titanium nitride (TiN), titanium silicon nitride (TiSiN) or other suitable materials chosen for compatibility.

In addition, a first gate material 140a is formed on the substrate 100. Specifically, first, the first gate material 140a is deposited over the active region AA and the isolation region 103 and completely fills the gate trench TR1. Next, a CMP process is performed to remove portions of the first gate material 140a over the top surface 101TS of the substrate 101. As a result, a remaining portion of the first gate material 140a surrounded by the first barrier layer 130a completely fills the gate trench TR1 in the active region AA. In some embodiments, the first gate material 140a may be formed using a CVD process, a physical vapor deposition (PVD) process, or an electroplating process. In some embodiments, the first gate material 140a includes various metals such as aluminum (Al), copper (Cu), tungsten (W), titanium (Ti), or other suitable materials with proper work function. In some embodiments, before the first gate material 140a is deposited over the first barrier layer 130a, a metal seed layer is conformally formed on the first barrier layer 130a to improve adhesion between the first barrier layer 130a and the subsequently-formed first gate material 140a. A material of the metal seed layer is selected in accordance with the material chosen for the first gate material 140a.

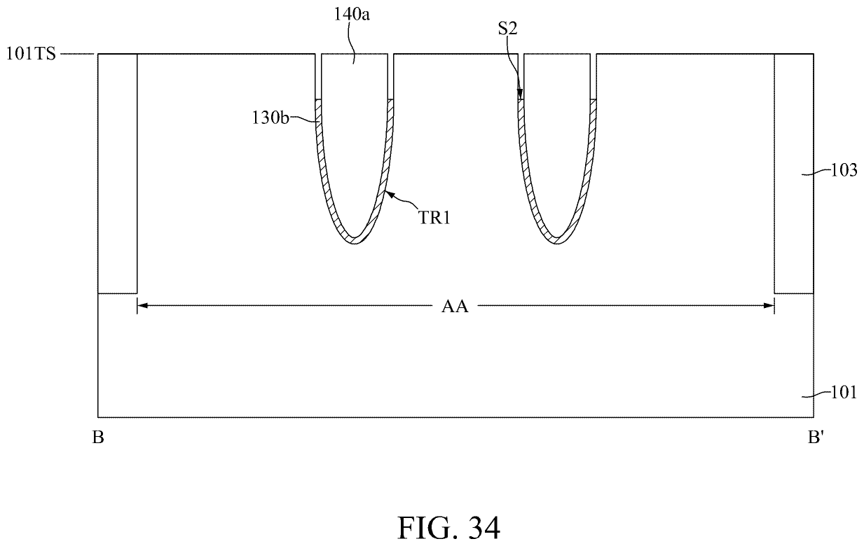

With reference to FIGS. 34 to 37, a recess is produced within the gate trench TR1. In some embodiments, the first barrier layer 130a and the first gate material 140a are sequentially recessed and shaped to different profiles. First, referring to FIG. 34, portions of the first barrier layer 130a are removed using a first etching process such that a remaining first barrier layer 130b is left. In some embodiments, the first barrier layer 130b has a top surface S2 lower than the top surface 101TS of the substrate 101.

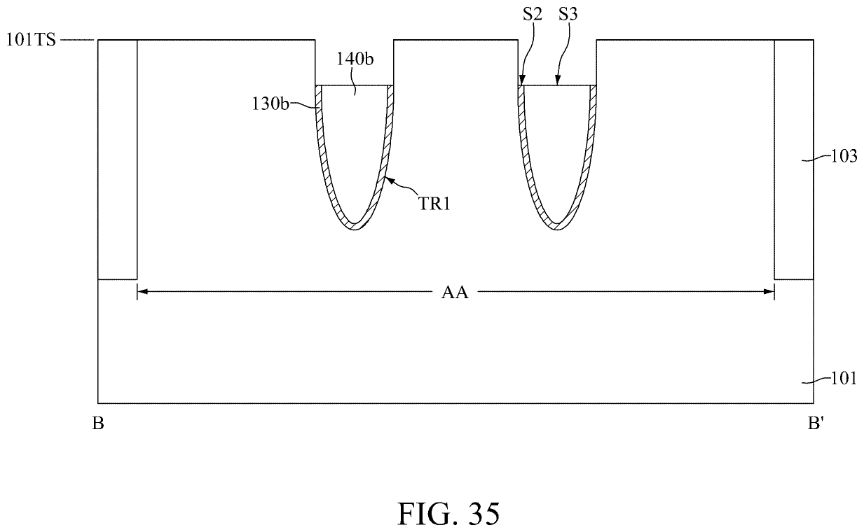

Next, referring to FIG. 35, a portion of the first gate material 140a is removed using a second etching process such that a remaining first gate material 140b is left. In some embodiments, the second etching process uses an etchant different from that used in the first etching process. The second etching process is an anisotropic etching that vertically removes about one-third of the height of the first gate material 140a. In some embodiments, after the second etching process is performed, the first gate material 140b has a top surface S3 substantially coplanar with the top surface S2 of the first barrier layer 130b.

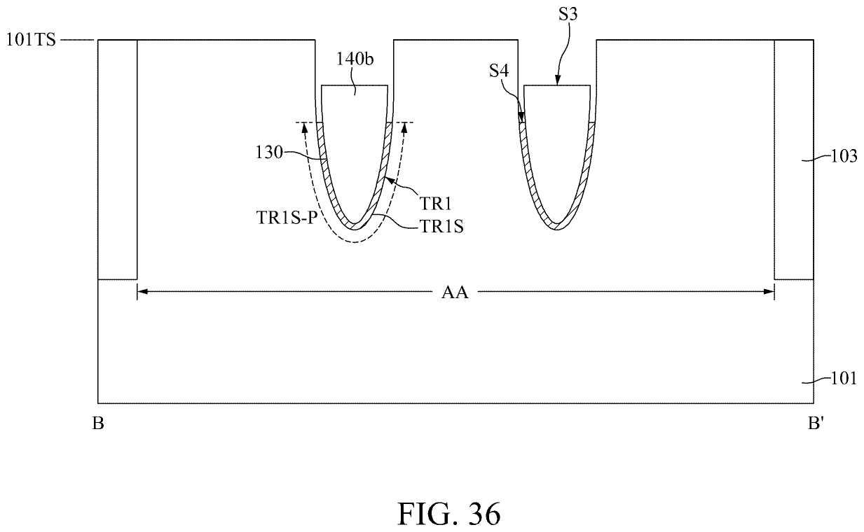

Subsequently, referring to FIG. 36, portions of the first barrier layer 130b are removed using a third etching process such that a remaining first barrier layer 130 is left. In some embodiments, the third etching process uses an etchant same as that of the first etching process. In some embodiments, after the third etching process is performed, the first barrier layer 130 has a top surface S4 substantially lower than the top surface S3 of the first gate material 140b.

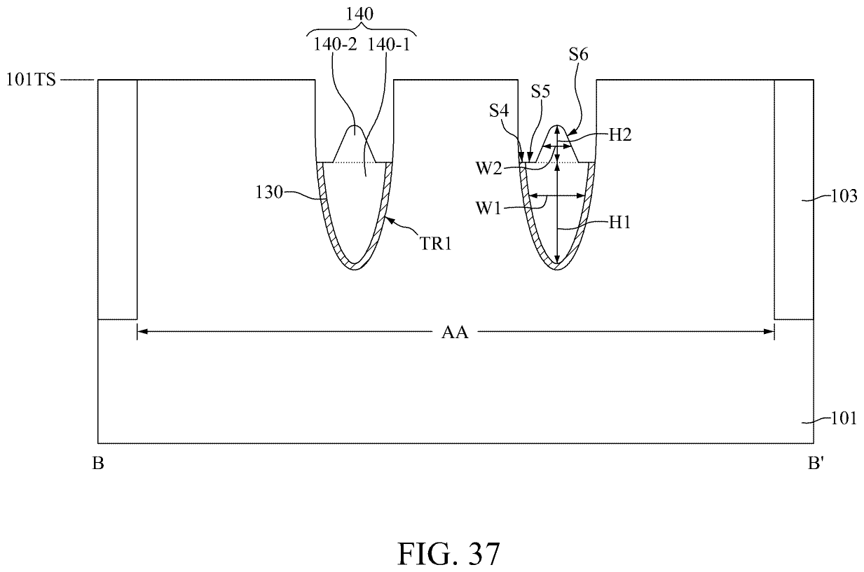

Next, referring to FIG. 37, a portion of the first gate material 140b is removed using a fourth etching process such that a remaining first gate material 140 is left. In some embodiments, the fourth etching process uses an etchant same as that of the third etching process. The fourth etching process mainly etches sidewalls of the first gate material 140b higher than a level of the top surface S4 and forms a rounded upper portion of the first gate material 140b. As seen by comparing FIG. 37 to FIG. 33, the first gate material 140a is etched to form the mound-shaped first gate material 140. Specifically, the first gate material 140 includes a first member 140-1 and a second member 140-2 positioned on the first member 140-1. The second member 140-2 extends from the first member 140-1 toward the top surface 101TS of the substrate 101. In some embodiments, the first member 140-1 has a hemi-ellipsoid profile and the second member 140-2 has a bell-shaped profile. In some embodiments, the first member 140-1 and the second member 140-2 have different dimensions. In some embodiments, the first member 140-1 has a first width W31 that varies at different vertical levels and a first height H1. In some embodiments, the second member 140-2 has a second width W32 that varies at different vertical levels and a second height H2. In some embodiments, the first member 140-1 has a substantially planar top surface S5 adjacent to and coplanar with the top surface S4 of the first barrier layer 130. In some embodiments, the second member 140-2 has a substantially convex top surface S6 surrounded by and extending from the top surface S5. The first member 140-1 is surrounded by the first barrier layer 130 while the second member 140-2 is not covered by any barrier layer.

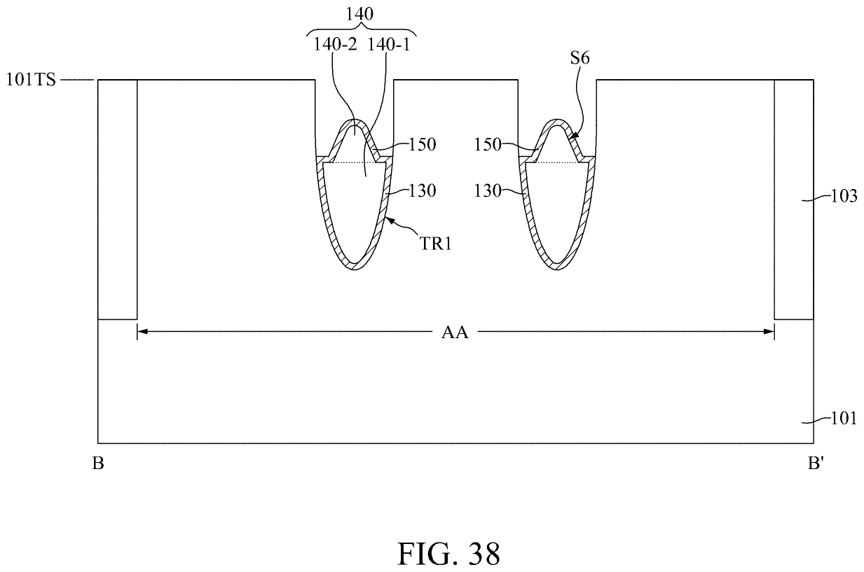

With reference to FIG. 38, a second barrier layer 150 is formed on the substrate 101. Specifically, the top surface S5 of the first member 140-1 and the top surface S6 of the second member 140-2 are covered by the second barrier layer 150. As a result, the first gate material 140 is completely encased by the first barrier layer 130 and the second barrier layer 150. In some embodiments, the second barrier layer 150 may include materials and may be formed by process procedures same as those of the first barrier layer 130.

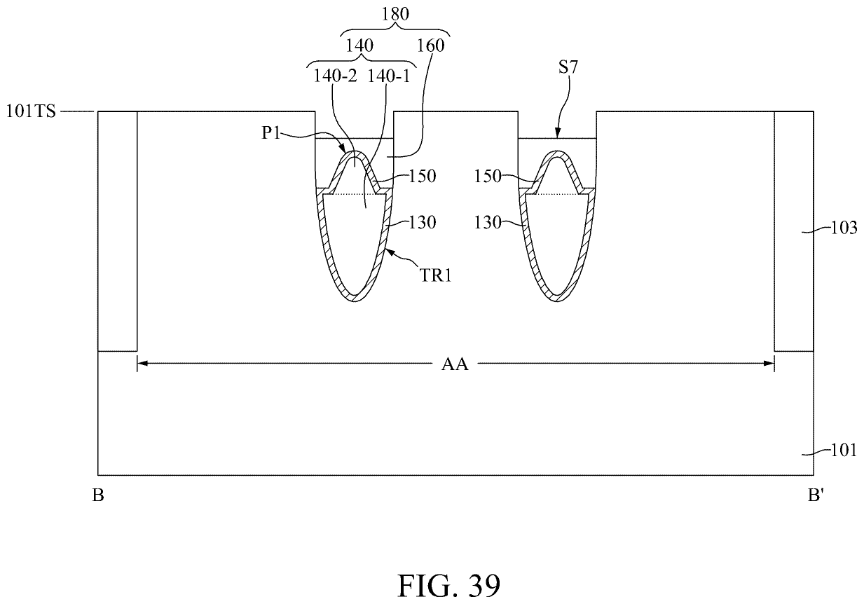

With reference to FIG. 39, a second gate material 160 is formed on the substrate 101. Specifically, the second gate material 160 is deposited to completely cover the first gate material 140 and partially fills the gate trench TR1. In some embodiments, the second gate material 160 has a top surface S7 substantially lower than the top surface 101TS of the substrate 101. In some embodiments, the second gate material 160 may include doped or undoped polycrystalline silicon formed using an LPCVD process. Preferably, the second gate material 160 is polycrystalline silicon doped with an impurity such that a resistance of the second gate material 160 is decreased. In some embodiments, a resistance of the first gate material 140 is lower than that of the second gate material 160. In some embodiments, a work function of the first gate material 140 is greater than that of the second gate material 160. In some embodiments, the first gate material 140 is used as a metal gate electrode and the second gate material 160 is used as a polysilicon gate electrode. The metal gate electrode 140 and the polysilicon gate electrode 160 may together form a buried dual gate electrode in a transistor in a DRAM device. In some embodiments, a buried gate electrode 180, including the first gate material 140 and the second gate material 160, is formed within the gate trench TR1 and functions as the transistor, wherein the buried gate electrode 180 has dual work functions. In the buried gate electrode 180, the second member 140-2 of the first gate material 140 extends toward the second gate material 160. The second barrier layer 150 is interposed between the second gate material 160 and the first gate material 140. The first barrier layer 130 and the second barrier layer 150 completely separate the first gate material 140 and the second gate material 160. Therefore, a reaction between the first gate material 140 and the second gate material 160 to form metal silicide can be prevented. In addition, the first barrier layer 130 and the second barrier layer 150 prevent mutual ion diffusion between the buried gate electrode 180 and an impurity region.

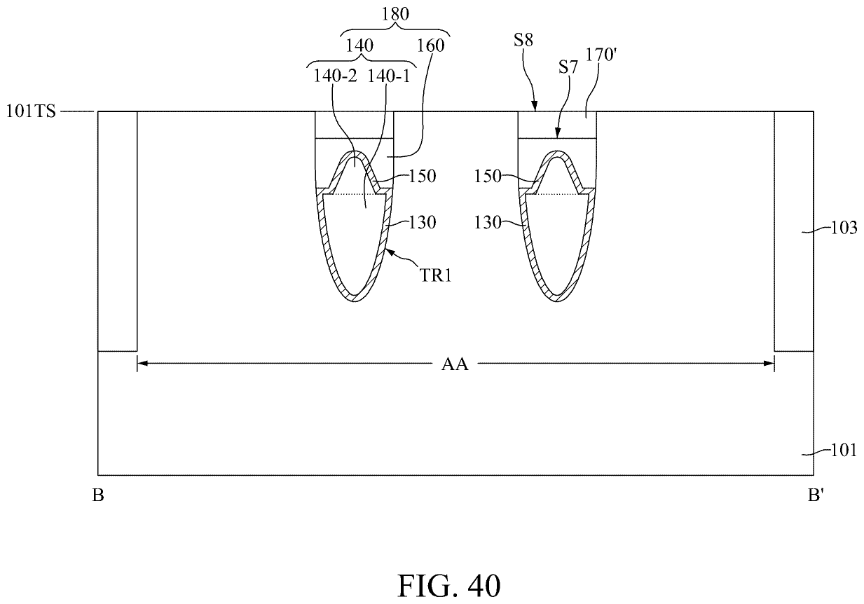

With reference to FIG. 40, a gate insulating material 170′ is formed on the substrate 101. Specifically, the gate insulating material 170′ is deposited to completely cover the second gate material 160 and partially fills the gate trench TR1. In some embodiments, the gate insulating material 170′ has a top surface S8 substantially coplanar with the top surface 101TS of the substrate 101. In some embodiments, the gate insulating material 170′ may be formed using a CVD process. In some embodiments, the gate insulating material 170′ includes a dielectric material such as silicon nitride (Si3N4) or other suitable materials. The gate insulating material 170′ may protect the buried gate electrode 180 and prevent an electrical short circuit from occurring.

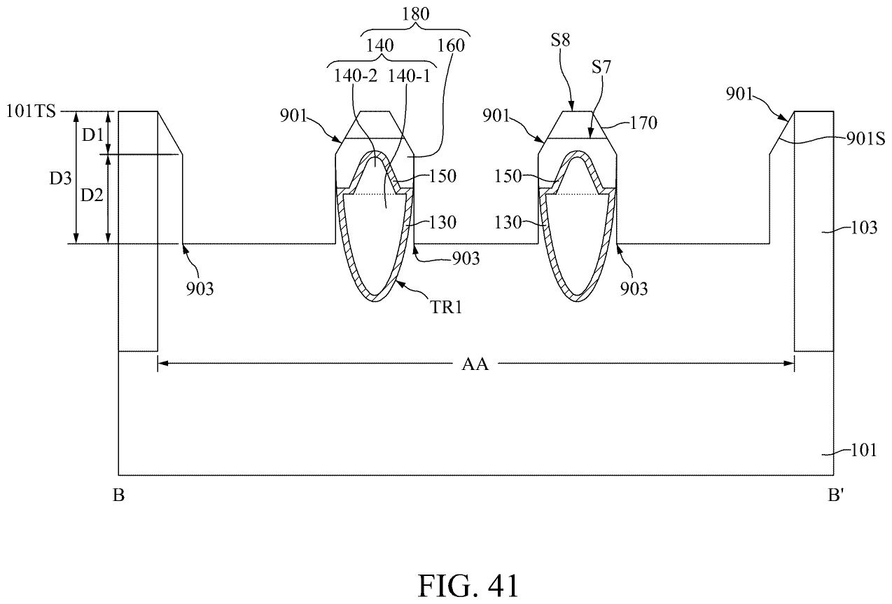

With reference to FIG. 41, a fifth etching process may be performed to remove portions of the substrate 101 and portions of the gate insulating material 170′ and concurrently form a plurality of first recesses 901 and gate insulating materials 170. For convenience of description, only one first recess 901 and one gate insulating material 170 are described. The first recess 901 may have two tapering sidewalls opposite to each other. A horizontal distance between the two tapering sidewalls may gradually decrease at positions of decreasing height along the direction Z. In some embodiments, the fifth etching process may be an isotropic plasma dry etch process. In some embodiments, the fifth etching process may be a wet etch process. Additionally, after the fifth etching process is performed, the gate insulating materials 170 may also have tapering sidewalls.

It should be noted that a selectivity of an etching process may be generally expressed as a ratio of etching rates. For example, if one material is etched 25 times faster than another material, the etching process may be described as having a selectivity of 25:1 or simply 25. In this regard, higher ratios or values indicate more selective etching processes.

In addition, a sixth etching process, such as an anisotropic plasma dry etch process, may be performed to remove portions of the substrate 101 and form a plurality of second recesses 903. In some embodiments, in the sixth etching process, an etching rate for the substrate 101 may be greater than an etching rate of the gate insulating material 170′. A selectivity of the sixth etching process may be greater than or equal to about 10, greater than or equal to about 12, greater than or equal to about 15, greater than or equal to about 20, or greater than or equal to about 25.

For convenience of description, only one second recess 903 is described. The second recess 903 may be extended from a bottom surface of the first recess 901. In some embodiments, a bottom surface of the second recess 903 may be curved. In some embodiments, the bottom surface of the second recess 903 may be flat. In some embodiments, the second recess 903 may have a U-shaped cross-sectional profile. Corner effects may be avoided if the second recess 903 has a U-shaped cross-sectional profile. A depth D1 of the first recess 901 may be equal to or less than one-fourth of a depth D2 of the second recess 903. In other words, the depth D1 of the first recess 901 may be equal to or less than one-fifth of a total depth D3 equal to a sum of the depth D1 of the first recess 901 and the depth D2 of the second recess 903.

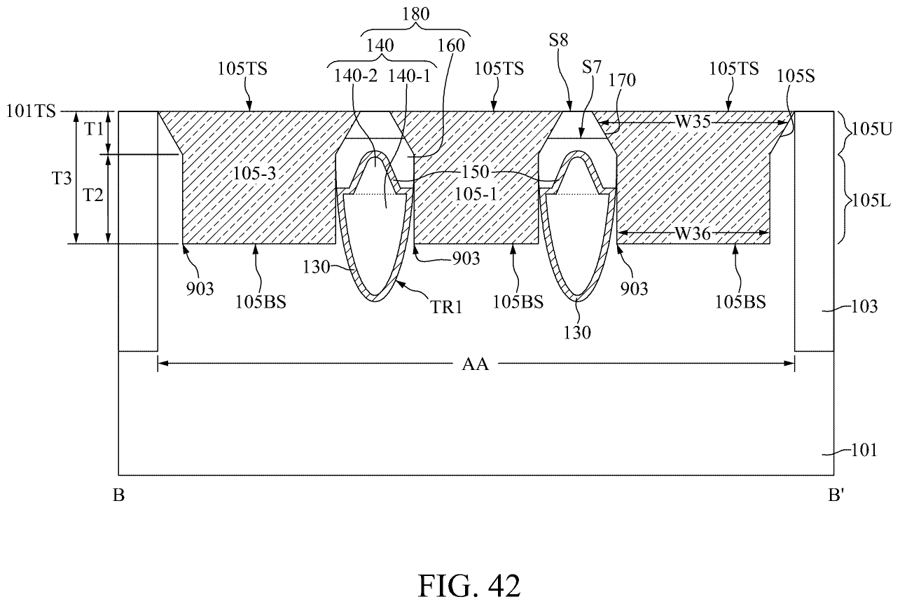

With reference to FIG. 42, an epitaxial growth process may be performed to fill the plurality of first recesses 901 and the plurality of second recesses 903 and concurrently form a plurality of impurity regions 105-1, 105-3. The epitaxial growth process may be chemical vapor deposition, atomic layer deposition, or molecular beam epitaxy. In some embodiments, a process temperature of the epitaxial growth process may be between about 700° C. and about 850° C. A process pressure of the epitaxial growth process may be between about 5 Torr and about 50 Torr. In some embodiments, a planarization process, such as chemical mechanical polishing, may be optionally performed to provide a substantially flat surface for subsequent processing steps. In some embodiments, the plurality of impurity regions 105-1, 105-3 may be formed to protrude from the top surface 101TS of the substrate 101.

A shape (or structure) of the plurality of impurity regions 105-1, 105-3 may be determined by shapes (or structures) of the plurality of first recesses 901 and the plurality of second recesses 903. The impurity region 105-1 may be located between the two buried gate electrodes 180. The impurity regions 105-3 may be respectively correspondingly located opposite to the impurity region 105-1 with two buried gate electrodes 180 interposed therebetween. The plurality of impurity regions 105-1, 105-3 may include upper portions 105U and lower portions 105L. The upper portions 105U of the plurality of impurity regions 105-1, 105-3 may be located at positions where the plurality of first recesses 901 were previously located. The lower portions 105L may be located at positions where the plurality of second recesses 903 were previously located.

For convenience of description, only one upper portion 105U and one lower portion 105L are described. The upper portion 105U may include two tapering sidewalls 105S. A horizontal distance between the two tapering sidewalls 105S (i.e., a width of the upper portion 105U) may gradually decrease at positions of decreasing height along the direction Z. The upper portion 105U may have a tapering cross-sectional profile. A thickness T1 of the upper portion 105U (i.e., a vertical distance between the top surface 105TS of the upper portion 105U and a bottommost point of the upper portion 105U) may be equal to or less than one-fourth of a thickness T2 of the lower portion 105L (i.e., a vertical distance between a bottom surface 105BS of the lower portion 105L and the bottommost point of the upper portion 105U). In other words, the thickness T1 of the upper portion 105U may be equal to or less than one-fifth of a total thickness T3 of the impurity region 105-1/105-3 (i.e., a vertical distance between the top surface 105TS of the upper portion 105U and the bottom surface 105BS of the lower portion 105L). In some embodiments, a width W35 of the top surface 105TS of the impurity region 105-1/105-3 is greater than a width W6 of the bottom surface 105BS of the impurity region 105-1/105-3.

In some embodiments, the plurality of impurity regions 105-1, 105-3 may be formed of, for example, silicon phosphide (SiP), phosphorus-doped silicon carbon (SiCP), silicon carbide (SiC), silicon germanium (SiGe), silicon-germanium-tin alloy (SiGeSn), silicon-germanium-boron alloy (SiGeB), or another suitable semiconductor material.

In some embodiments, the impurity region 105-1/105-3 may be doped with a dopant such as phosphorus or boron. A dopant concentration of the impurity region 105-1/105-3 may be uniform. In some embodiments, the dopant concentration of the impurity region 105-1/105-3 may be gradually increased at positions of increasing height within the impurity region 105-1/105-3. In some embodiments, a dopant concentration of the upper portion 105U may be greater than a dopant concentration of the lower portion 105L. In some embodiments, the dopant concentration of the upper portion 105U is gradually increased from the bottommost points to the top surface 105TS.

After the formation of the buried gate electrode 180 and the impurity regions 105-1, 105-3, followed by processes described in steps S13 to S17, a semiconductor device 1D shown in FIG. 31 is obtained.

One aspect of the present disclosure provides a semiconductor device comprising a substrate with an active region; a gate structure disposed in a gate trench in the active region; an impurity region disposed adjacent to the gate structure; at least two bit line structures positioned on the substrate; a contact layer positioned on the substrate and between the at least two bit line structures; and a conductive neck layer positioned on the contact layer and between the at least two bit line structures. The impurity region has an upper portion defining a top surface of the impurity region and a lower portion defining a bottom surface of the impurity region. A width of the top surface of the impurity region is greater than a width of the bottom surface of the impurity region.

Another aspect of the present disclosure provides a semiconductor device comprising a substrate having a first top surface; a first gate electrode and a second gate electrode disposed in the substrate, wherein the second gate electrode is positioned above the first gate electrode; a first barrier layer and a second barrier layer disposed in the substrate, wherein the second barrier layer is positioned over the first barrier layer and the first gate electrode; a gate capping layer disposed over the second gate electrode; at least two bit line structures positioned on the substrate; a contact layer positioned on the substrate and between the at least two bit line structures; and a conductive neck layer positioned on the contact layer and between the at least two bit line structures. The first gate electrode includes a first member surrounded by the first barrier layer and a second member extending from the first member toward the first top surface and protruding from the first barrier layer. The second gate electrode is positioned on the second barrier layer at a position such that the second gate electrode surrounds the second barrier layer and the second member of the first gate electrode. A width of a top surface of the conductive neck layer is greater than a width of a bottom surface of the conductive neck layer.

Another aspect of the present disclosure provides a method for fabricating a semiconductor device. The method includes providing a substrate having an isolation region, wherein the isolation region defines an active region; forming a gate structure in the substrate; forming at least two bit line structures on the substrate; forming at least two partition layers on the substrate; forming a contact layer on the substrate; and forming a conductive neck layer on the contact layer. A width of a top surface of the conductive neck layer is greater than a width of a bottom surface of the conductive neck layer.

Another aspect of the present disclosure provides a method for fabricating a semiconductor device. The method includes providing a substrate with a first top surface, wherein the substrate includes an isolation region surrounding an active region; forming a gate structure in the active region of the substrate; forming a first recess and a second recess in the substrate and adjacent to the gate structure; forming an impurity region in the first recess and in the second recess; forming at least two bit line structures on the substrate; forming at least two partition layers on the substrate; forming a contact opening over the substrate; forming a contact layer on the substrate and within the contact opening; and forming a conductive neck layer on the contact layer. The contact opening is enclosed by at least two partition layers and the at least two bit line structures. The impurity region has an upper portion defining a top surface of the impurity region and a lower portion defining a bottom surface of the impurity region. A width of the top surface of the impurity region is greater than a width of the bottom surface of the impurity region.

Due to a design of the semiconductor device disclosed herein, overlapping areas between the conductive neck layer 503 and the landing pad 505 can be increased by using a wider top surface 503TS for the conductive neck layer 503. As a result, defects and complexity associated with fabricating the semiconductor device 1A, 1B, 1C, and 1D are reduced.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A method for fabricating a semiconductor device, comprising:
providing a substrate having an isolation region, wherein the isolation region defines an active region;
forming a gate structure in the substrate;
forming at least two bit line structures on the substrate;
forming at least two partition layers on the substrate;
forming a contact layer on the substrate; and
forming a conductive neck layer on the contact layer;
wherein a width of a top surface of the conductive neck layer is greater than a width of a bottom surface of the conductive neck layer.

2. The method of claim 1, wherein the formation of the gate structure comprises:
forming a gate trench in the active region;
forming a first barrier layer on a portion of a sidewall of the gate trench;
forming a first gate material in the gate trench, wherein the first gate material comprises a first member surrounded by the first barrier layer and a second member extending from the first member toward the first top surface and protruding from the first barrier layer;
forming a second barrier layer on the first barrier layer and the first gate material; and
forming a second gate material on the second barrier layer at a position such that the second gate material surrounds the second barrier layer and the second member of the first gate material.

3. The method of claim 1, wherein, after the formation of the at least two partition layers, comprises:
forming a contact opening over the substrate, wherein the contact opening is enclosed by the at least two partition layers and the at least two bit line structures.

4. The method of claim 3, wherein the contact opening is filled by the contact layer and the conductive neck layer.

5. A method for fabricating a semiconductor device, comprising:
providing a substrate with a first top surface, wherein the substrate includes an isolation region surrounding an active region;
forming a gate structure in the active region of the substrate;
forming a first recess and a second recess in the substrate and adjacent to the gate structure;
forming an impurity region in the first recess and in the second recess;
forming at least two bit line structures on the substrate;
forming at least two partition layers on the substrate;
forming a contact opening over the substrate, wherein the contact opening is enclosed by at least two partition layers and the at least two bit line structures;
forming a contact layer on the substrate and within the contact opening; and
forming a conductive neck layer on the contact layer;
wherein the impurity region has an upper portion defining a top surface of the impurity region and a lower portion defining a bottom surface of the impurity region, wherein a width of the top surface of the impurity region is greater than a width of the bottom surface of the impurity region.

6. The method of claim 5, wherein the formation of the gate structure comprises:
forming a gate trench in the active region;
forming a first barrier layer on a portion of a sidewall of the gate trench;
forming a first gate material in the gate trench, wherein the first gate material comprises a first member surrounded by the first barrier layer, and a second member extending from the first member toward the first top surface and protruding from the first barrier layer;
forming a second barrier layer on the first barrier layer and the first gate material; and
forming a second gate material on the second barrier layer.

7. The method of claim 5, wherein the formation of the first recess and the second recess comprises:
performing an isotropic etching process to form the first recess in the substrate, wherein the first recess comprises tapering sidewalls; and
performing an anisotropic etching process to expand the first recess and form a second recess below the first recess.

8. The method of claim 5, further comprising:
conformally forming a plurality of inner spacer layers on sides of the at least two bit line structures.

9. The method of claim 8, further comprising:
conformally forming a plurality of outer spacer layers on the plurality of inner spacer layers.

10. The method of claim 5, further comprising:
forming a landing pad positioned on the conductive neck layer, wherein the landing pad and the conductive neck layer are partially overlapped in a top-view perspective.
